(19) United States
(12) Patent Application Publication
(10) Pub. No.: US 2025/0378815 A1
(43) Pub. Date: Dec. 11, 2025

(54) ADAPTIVE DIGITAL FEEDBACK REDUCTION

(71) Applicant: Shure Acquisition Holdings, Inc., Niles, IL (US)

(72) Inventors: Kenneth Boysen, Copenhagen (DK); Bijal Joshi, Schaumburg, IL (US); Dave VerLee, Libertyville, IL (US)

(73) Assignee: Shure Acquisition Holdings, Inc., Niles, IL (US)

(21) Appl. No.: 19/179,664

(22) Filed: Apr. 15, 2025

Related U.S. Application Data
(60) Provisional application No. 63/656,440, filed on Jun. 5, 2024.

(51) Int. Cl. G10K 11/178; H03G 3/30

(52) U.S. Cl. CPC G10K 11/17853; H03G 3/3089; G10K 2210/3026

(57) ABSTRACT

Methods and apparatuses are described to provide digital feedback reduction (DFR) that may reduce or eliminate the presence of feedback in digital audio signals. The DFR techniques as described herein may implement a fast and reliable detection process to help ensure a minimal false detection probability. Furthermore, the DFR techniques as described herein may support a wider frequency range compared to conventional DFR techniques, for instance from 20 Hz up to at least 20 kHz.

### CROSS-REFERENCE TO RELATED APPLICATIONS

This application claims priority to U.S. provisional application no. 63,656,440, filed on Jun. 5, 2024, the contents of which are incorporated herein by reference in their entirety.

### FIELD

Aspects described herein generally relate to audio signal processing, and more particularly, to techniques for performing digital feedback reduction (DFR) in audio systems.

### BACKGROUND

Audio systems often implement a variety of input and output devices, such as microphones and speakers, respectively. Microphones may include, for instance, handheld microphones, boundary microphones, body microphones, etc., which may have omnidirectional and/or very broad pickup patterns. Moreover, the specific environment, the input and output devices, as well as the spatial relationship among these input and output devices may vary significantly between different end users and for different use cases. As a result, audio feedback inevitably occurs during audio system operation, which needs to be addressed to provide a good user experience.

To this end, conventional audio feedback reduction techniques include the use of digital feedback reduction (DFR) algorithms, which attempt to actively identify feedback tones via a frequency tracking system. Once identified, such conventional DFR algorithms attempt to filter out any detected feedback tones from the audio pipeline using digital notch filters. However, once such notch filters are applied, conventional DFR algorithms do not provide any automated mechanism for removing the notch filters to avoid a reintroduction of the same feedback.

Additionally, conventional DFR algorithms have drawbacks in that the feedback frequency tracking is very “quantized.” As a result, conventional DFR algorithms fail to provide reliable detection of the feedback frequency, particularly for bass frequencies (e.g. frequencies below 200 Hertz). Moreover, conventional DFR algorithms are typically not configured to detect feedback at frequencies above ¼ of the sample rate. For example, for an 48 kHz audio sampling system, conventional DFR algorithms may be unable to detect feedback at frequencies above 12 kHz. Further still, conventional DFR algorithms are not configured to perform alternative feedback mitigation techniques such as system gain reduction.

### SUMMARY

The following presents a simplified summary of the disclosure to provide a basic understanding of some aspects of the disclosure. This summary is not an extensive overview of the disclosure. It is not intended to identify key or critical elements of the disclosure or to delineate the scope of the disclosure. The following summary merely presents some concepts of the disclosure in a simplified form as a prelude to the more detailed description provided below.

Again, conventional DFR algorithms have various drawbacks. The aspects described herein provide improved DFR techniques and an accompanying architecture that addresses these aforementioned drawbacks. To do so, the DFR techniques as described herein implement a fast and reliable detection process and, at the same time, ensure a reduction in false detections. Furthermore, the DFR techniques as described herein support a wider frequency range compared to conventional DFR techniques, for instance from 20 Hertz up to a minimum of 20 KHz.

The DFR techniques as described herein may advantageously be implemented in audio systems that yield unstable feedback frequencies that change or drift over time. This may be the case, for example, in audio systems that implement wireless microphones that cause unstable feedback by way of their movement within the environment. Additionally, the DFR techniques as described herein may be configured to apply notch filters and/or a system gain reduction to mitigate any detected feedback.

Still further, the DFR techniques as described herein may support an automated release option with respect to the application of any notch filters on the audio output pipeline while ensuring that doing so will not immediately reintroduce any presently-mitigated feedback. This automated release option may be particularly useful, for example, for audio systems that have an invalid or improper gain setup. Additionally, such an automated release option may be valuable in user scenarios in which the setup is not fixed and/or the coupling between speakers and microphones change characteristics over time.

The DFR techniques as described in further detail herein may include the use of a DFR algorithm. In such a case, the DFR techniques as discussed herein may be implemented in accordance with any suitable programming language (e.g. a C implementation), and may be suitable for any suitable benchmarking framework (e.g. Olympus, Flex, etc.). The DFR techniques as discussed herein may additionally support any suitable type of simulation environment, such as Matlab, C++, etc., and may be implemented as part of a Microprocessor without Interlocked Pipeline Stages (MIPS) architecture. Thus, by being “MIPS friendly,” the DFR techniques as discussed herein facilitate scalability and enable a diverse application to various products with different chipsets.

The DFR algorithms as discussed in further detail herein may detect feedback at specific frequencies and react on the onset of such detected feedback. In doing so, such DFR algorithms may not interfere with and/or introduce any kind of audio distortion on a live audio signal unless there is feedback present in the system. The DFR algorithms described herein use a variety of filters, such as adaptive lattice filters for example, to track the strongest frequency in the spectrum, and implement adaptive isolation filters to separate the fundamental and harmonic components of a feedback signal. As part of this implementation, the DFR algorithms may search for intermediate harmonics and lower harmonics to support a detection up to ½ of the sampling rate.

As discussed in further detail herein, the DFR algorithms may evaluate both absolute levels and relative ratios as part of the predefined conditions that are used to detect the presence of audio feedback. Once detected, feedback mitigation procedures and release procedures are implemented to dynamically apply feedback reduction techniques (e.g. filters such as notch filters, system gain reduction, etc.) and to attempt to remove the applied feedback reduction techniques as needed. In some examples, smoothing may be used to avoid “clicks” and “pops” as the notch filters or system gain reduction is applied and removed, and thus the functionality of the DFR algorithms may be split between frame-based processing and sample-based processing, as further discussed below.

As described in more detail herein, this application sets forth methods, algorithms, apparatuses, and systems for dynamically detecting and mitigating detected audio feedback via the application of various feedback reduction techniques, as well as dynamically removing the applied feedback reduction techniques to ensure a good user experience.

An example method may comprise receiving a composite digital reference signal that is based upon the digital audio signal; detecting feedback within the composite digital reference signal based on: an energy level measurement of a fundamental frequency component of a candidate signal of the composite digital reference signal satisfying a first predetermined threshold energy value, and a plurality of previous energy level measurements of the fundamental frequency component of the candidate signal over a time interval satisfying a second predetermined threshold energy value; and executing, based upon detecting the feedback within the digital reference signal, a feedback mitigation procedure to reduce feedback in the digital audio signal.

An example non-transitory computer-readable medium may comprise one configured to store instructions thereon that, when executed by one or more processors, cause the one or more processors to perform adaptive feedback reduction in a digital audio signal by: detecting feedback within a composite digital reference signal that is based upon the digital audio signal based on: an energy level measurement of a fundamental frequency component of a candidate signal of the composite digital reference signal satisfying a first predetermined threshold energy value, and a plurality of previous energy level measurements of the fundamental frequency component of the candidate signal over a time interval satisfying a second predetermined threshold energy value; and executing, based upon detecting the feedback within the digital reference signal, a feedback mitigation procedure to reduce feedback in the digital audio signal.

These as well as other novel advantages, details, examples, features and objects of the present disclosure will be apparent to those skilled in the art from following the detailed description, the attached claims and accompanying drawings, listed herein, which are useful in explaining the concepts discussed herein.

### BRIEF DESCRIPTION OF THE DRAWINGS

Some features are shown by way of example, and not by limitation, in the accompanying drawings. In the drawings, like numerals reference similar elements.

FIG. 1 illustrates a block diagram of an example audio system that may be used to implement one or more illustrative aspects described herein.

FIG. 2A illustrates an example block diagram of a first example digital feedback reduction (DFR) architecture that may be used to implement one or more illustrative aspects described herein.

FIG. 2B illustrates an example block diagram of a second example digital feedback reduction (DFR) architecture that may be used to implement one or more illustrative aspects described herein.

FIG. 2C illustrates an example block diagram providing additional details with respect to the second example digital feedback reduction (DFR) architecture as shown in FIG. 2B.

FIG. 3A illustrates an example spectral signature of a feedback signal.

FIG. 3B illustrates an example time-domain signature of a voice signal.

FIG. 4 illustrates an example flow chart of a method that may be performed to implement one or more illustrative aspects described herein.

FIG. 5 is a block diagram showing example details of an audio device that may be part of an audio system, such as the audio system of FIG. 1.

FIG. 6 is a block diagram showing example details of an audio device that may be part of an audio pipeline and used to implement one or more illustrative aspects described herein.

### DETAILED DESCRIPTION

In the following description of the various examples, reference is made to the accompanying drawings, which form a part hereof, and in which is shown by way of illustration various examples in which aspects may be practiced. References to “embodiment,” “example,” “aspect,” and the like indicate that the embodiment(s) or example(s) of the disclosure so described may include particular features, structures, or characteristics, but not every embodiment or example necessarily includes the particular features, structures, or characteristics. Further, it is contemplated that certain embodiments or examples may have some, all, or none of the features described for other examples. And it is to be understood that other embodiments and examples may be utilized and structural and functional modifications may be made without departing from the scope of the present disclosure.

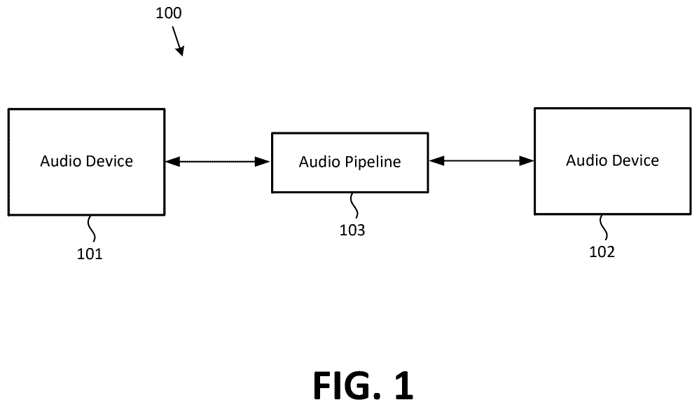

FIG. 1 illustrates a block diagram of an example audio system that may be used to implement one or more illustrative aspects described herein. The audio system 100 may comprise a plurality of audio devices, such as audio device 101 and audio device 102. The plurality of audio devices may be communicatively coupled to one another via an audio pipeline 103, which may comprise any suitable type of medium. For instance, the audio pipeline 103 may comprise one or more hardware and/or software components configured to perform digital feedback reduction (DFR) techniques on audio signals as part of a feedback mitigation procedure, which are discussed in further detail herein. The audio pipeline 103 may couple audio signals received from the audio device 101 to the audio device 102, and vice-versa.

The audio pipeline 103 may be implemented as part of a device that is co-located in the same environment as the audio devices 101, 102. In this scenario, the audio pipeline 103 may be implemented as part of any suitable type of audio device, which may interface with the audio devices 101, 102 via any suitable configuration of wired and/or wireless ports, interfaces, etc. For instance, the audio pipeline 103 may be implemented as part of an audio device in which the audio devices 101, 102 are connected as part of the audio system 100, which may be used in any suitable environment in which the audio devices 101, 102 are also used. The audio devices 101, 102 and the audio pipeline 103 may be co-located, or any combination of the audio devices 101, 102 and the audio pipeline 103 may be co-located or located remote from one another. The audio pipeline 103 is configured to couple the audio signals received via the audio device 101 to the audio device 102 and, in doing so, to perform any suitable type of audio processing such as digital signal processing (DSP), filtering, etc., which may be part of the DFR techniques as discussed herein or separate audio processing operations.

As another example, the audio pipeline 103 may be implemented as part of a communication network (e.g., a cloud computing device, a server, etc.) and/or may be coupled to the audio devices 101, 102 via such a communication network. Thus, the various aspects as described herein may be performed by the audio pipeline 103, which may include the execution of one or more DFR techniques as further discussed herein. In this way, the DFR techniques as discussed herein may be performed locally, such as in the same environment as the audio devices 101, 102 or, alternatively, at a location that is remote to the audio devices 101, 102.

In any event, because the DFR algorithms as discussed herein operate in the digital domain, the audio pipeline 103 may comprise any suitable type of software components in addition to hardware components (e.g., analog-to-digital converters (ADCs)), which may be configured to convert analog audio signals received from the audio devices 101, 102 to digital samples in accordance with any suitable sampling rate. Additionally, the audio pipeline 103 may comprise any suitable type of hardware components (e.g., digital-to-analog converters (DACs)) configured to convert digital samples of the audio signals output from the audio pipeline 103 to an analog audio signal that is coupled to the audio devices 101, 102.

The audio devices 101, 102 may comprise any suitable type of device that is capable of sending, receiving, and/or processing (e.g., modifying, storing, and/or operating in response to) audio. Non-limiting examples of audio devices include devices that are, or that include, microphones, speakers, conferencing equipment, audio recorders, personal computers, servers, display devices (e.g., television or computer displays), networking devices, audio mixers, and musical instruments. For example, the audio device 101 may be or otherwise include a microphone, and the audio device 102 may be or otherwise include a speaker. Each of the audio devices 101, 102 may comprise any suitable number and/or type of individual components, e.g., several microphones, speakers, etc., interconnected via the audio pipeline 103, and thus the audio system 100 may comprise a multiple-input, multiple-output audio system in such cases

Audio data that is generated based on sound detected by the microphone may be sent by the audio device 101 as one or more audio signals, via the audio pipeline 103, to at least the audio device 102. The audio device 102 may accordingly cause its speaker to generate sound based on the received audio data. This is but one example—as another example, each of the audio devices 101 and 102 may include both a microphone and a speaker. As a further example, the audio device 101 may include a microphone and the audio device 102 may include a computing device configured to store audio data received from the audio device 101. As a further example, the audio devices 101 and 102 may each be elements of a teleconferencing or videoconferencing system. As a further example, the audio devices 101 and 102 may each be elements of a public address system.

When implemented as part of the audio pipeline 103, the communication network may be any suitable type of network (including a simple connection between audio devices 101, 102) using any suitable number and/or type of protocols. For example, the communication network may utilize Internet Protocol (IP) to carry data such as audio data in IP datagrams. The communication network may send such IP datagrams using a particular data link layer protocol, such as Ethernet. This combination of IP and Ethernet is known as IP Over Ethernet (IPoE), in which data (such as audio data) is placed in IP datagrams, and the IP datagrams are encapsulated in Ethernet frames. The term “packet” will be used herein to include various organized groupings of data, such as but not limited to datagrams (for example, User Data Protocol (UDP) datagrams) and frames.

Each of the audio devices 101, 102 may therefore be configured to send, via the audio pipeline 103, data to one or more other audio devices. Each of the audio devices 101, 102 may further be configured to receive, via the audio pipeline 103, data from one or more other audio devices. Any of the audio devices may be configured to both send and receive data, to exclusively send data, or to exclusively receive data. For example, the audio device 101 may be configured to send and/or receive data via the audio pipeline 103 to and/or from the audio device 102, and the audio device 102 may be configured to send and/or receive data via the audio pipeline 103 to and/or from the audio device 101. The data sent between the audio devices may include audio data, video data, communication control data, system control data, audio processing parameter data, and/or any other suitable types of data.

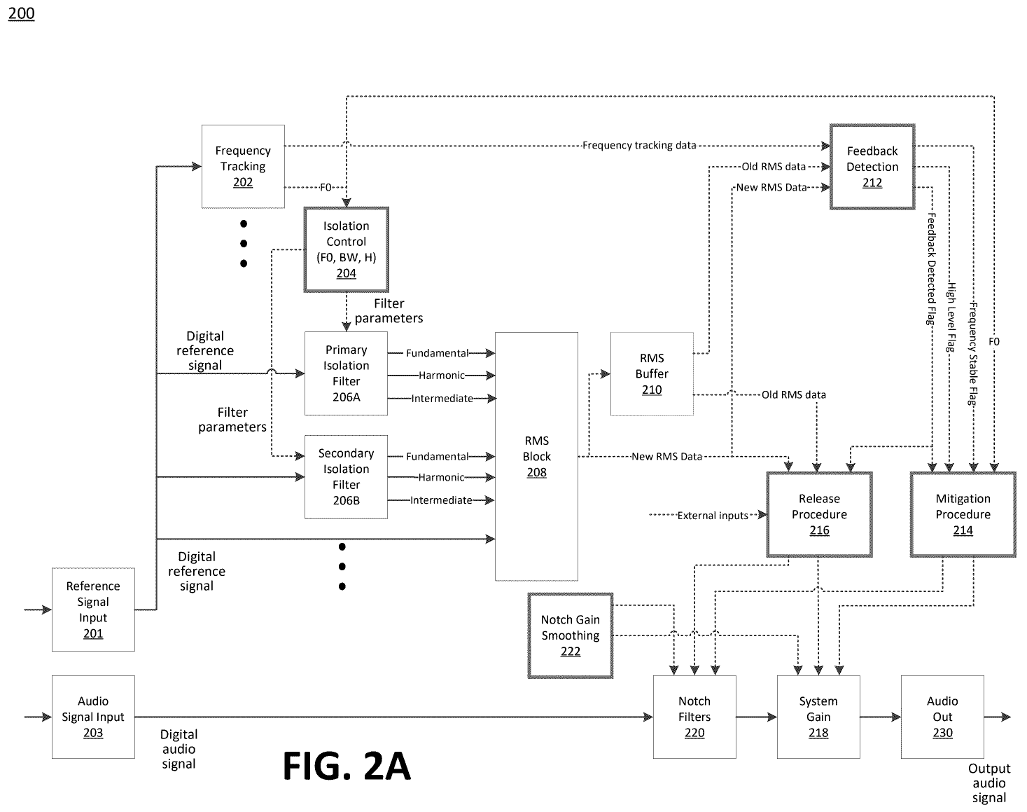

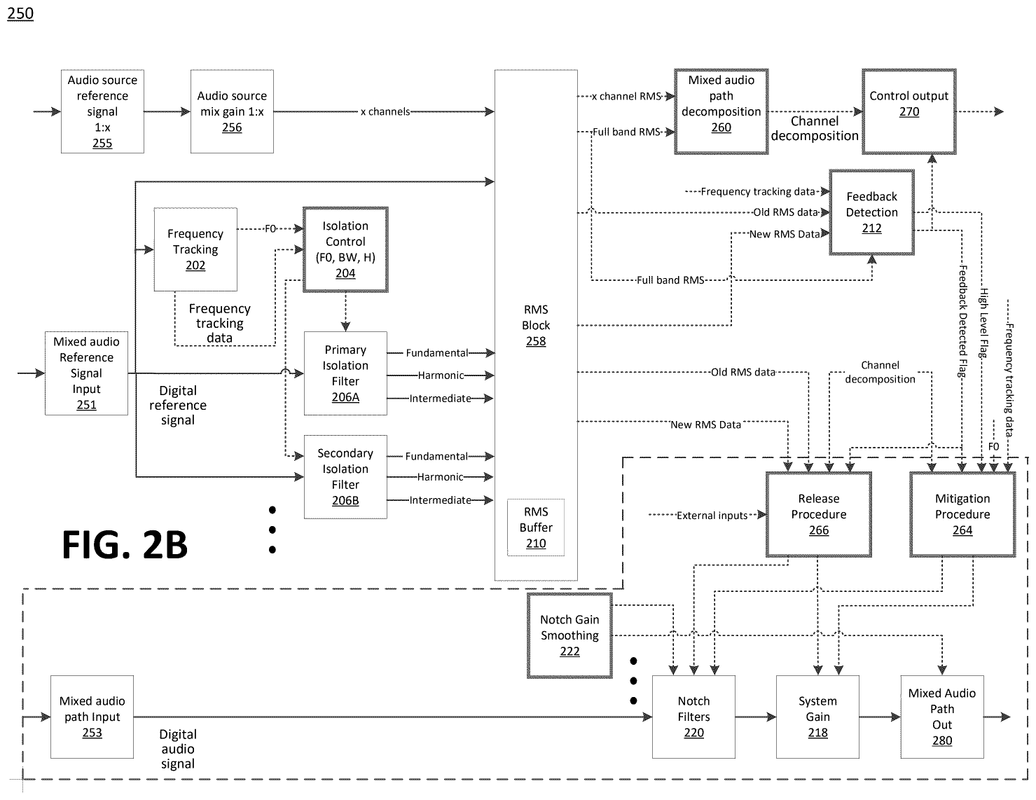

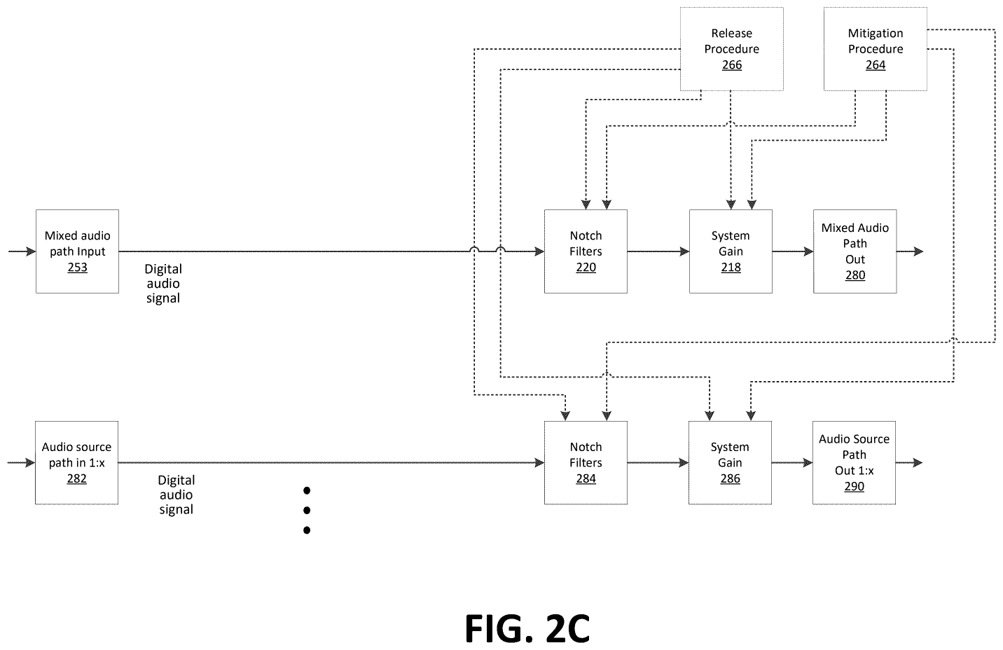

FIG. 2A illustrates an example block diagram of an example digital feedback reduction (DFR) architecture that may be used to implement one or more illustrative aspects described herein. The DFR architecture 200 as shown in FIG. 2A may implement software, hardware components, or combinations of these. For example, the DFR architecture 200 as shown in FIG. 2A may comprise several functional blocks, and each of these blocks may represent the functionality associated with the execution of software, hardware components, or combinations of these. The DFR architecture 200 may, in some aspects, facilitate the execution of a DFR algorithm, and in such a case the various functional blocks as shown may represent the execution of software to achieve the corresponding results as discussed herein.

The DFR architecture 200 may be implemented via any suitable platform, and may represent the entirety of or a portion of the audio pipeline 103 as discussed above with respect to FIG. 1 or, alternatively, as any suitable portion of the audio devices 101, 102. Any suitable components identified with the DFR architecture 200 may be implemented as any suitable portions of the audio system 100, and may be divided among the audio device 101, 102, and/or the audio pipeline 10. Alternatively, the components identified with the DFR architecture 200 may be included entirely as part of the audio devices 101, 102, and/or the audio pipeline 103. Thus, the DFR architecture 200 may be implemented via any suitable device, which may comprise any suitable type of hardware components, processors, processing circuitry, etc., suitable for this purpose, and which may control the overall operation of the DFR architecture 200. Various aspects described herein may be embodied as a method, a system, an apparatus, or a computer program product. Therefore, various functionalities may be embodied in whole or in part in software, firmware, and/or hardware or hardware equivalents such as integrated circuits, field programmable gate arrays (FPGA), and the like. Particular data structures may be used to more effectively implement one or more aspects described herein, and such data structures are contemplated within the scope of computer executable instructions and computer-usable data described herein. Examples of other computing systems, environments, and/or configurations that may be suitable for use with aspects described herein include, but are not limited to, personal computers, server computers, hand-held or laptop devices, multiprocessor systems, microprocessor-based systems, set top boxes, programmable consumer electronics, network personal computers (PCs), minicomputers, mainframe computers, distributed computing environments that include any of the above systems or devices, and the like.

One or more aspects of the DFR architecture 200 may be embodied in computer-usable or readable data and/or computer-executable instructions, such as in one or more program modules, executed by one or more computers or other devices as described herein. Generally, program modules include routines, programs, objects, components, data structures, etc. that perform particular tasks or implement particular abstract data types when executed by a processor in a computer or other device. The modules may be written in a source code programming language that is subsequently compiled for execution, or may be written in a scripting language such as (but not limited to) Python, Perl, PHP, Ruby, JavaScript, and the like. The computer executable instructions may be stored on a computer readable medium such as a nonvolatile storage device. Any suitable computer readable storage media may be utilized, including hard disks, CD-ROMs, optical storage devices, magnetic storage devices, solid state storage devices, and/or any combination thereof.

The arrows as shown in FIG. 2A define different flows associated with the DFR architecture 200. For instance, the solid lined arrows may represent audio flow data, whereas the dashed lined arrows may represent control flow data. Additionally, the thick-bordered blocks as shown in FIGS. 2A-2C may implement frame-based processing, whereas the remaining blocks may implement sample-based processing. As shown in FIG. 2A, the DFR architecture 200 comprises two input ports: a reference signal input block 201 and an audio signal input block 203. Again, the DFR architecture 200 operates in the digital domain, and thus the various audio signals provided with respect to the reference signal input block 201 and the audio signal input block 203 are digitized audio signals that have been sampled in accordance with any suitable sampling rate. The audio signal input block 203 may be identified with the digitization of a received audio signal to provide a digital audio signal, which may be provided via the audio device 101 for example as discussed above. The digital audio signal may thus be generated from an audio signal that is received via a microphone for example, at a corresponding system port.

The reference signal input block 201 may be identified with the digitization of a reference audio signal to provide a digital reference signal, which again may be provided via the audio device 101 for example as discussed above. The digital reference signal and the digital audio signal may comprise the same signal, in some aspects. Alternatively, the digital reference signal and the digital audio signal may comprise different audio signals. For example, the reference signal input block 201 may represent a reference input port, which provides the digital reference signal as the audio sample that is received via the DFR architecture 200 and used to extract audio signal information that is used in accordance with the various DFR techniques as discussed herein. However, the audio signal input block 203 may represent a separate audio input port that provides the digital audio signal, which may represent a live or raw audio sample, to which the notch filters and system gain may be applied before the audio is sent to the next stage within the overall audio pipeline 103. Thus, the reference input port (block 201) and the audio signal input port (block 203) may be identified with the same location and/or stage or a different location and/or stage within the audio pipeline 103. In this way, the use of two ports may facilitate a DFR process that provides flexibility and allows for the adaptation to different audio chain architectures.

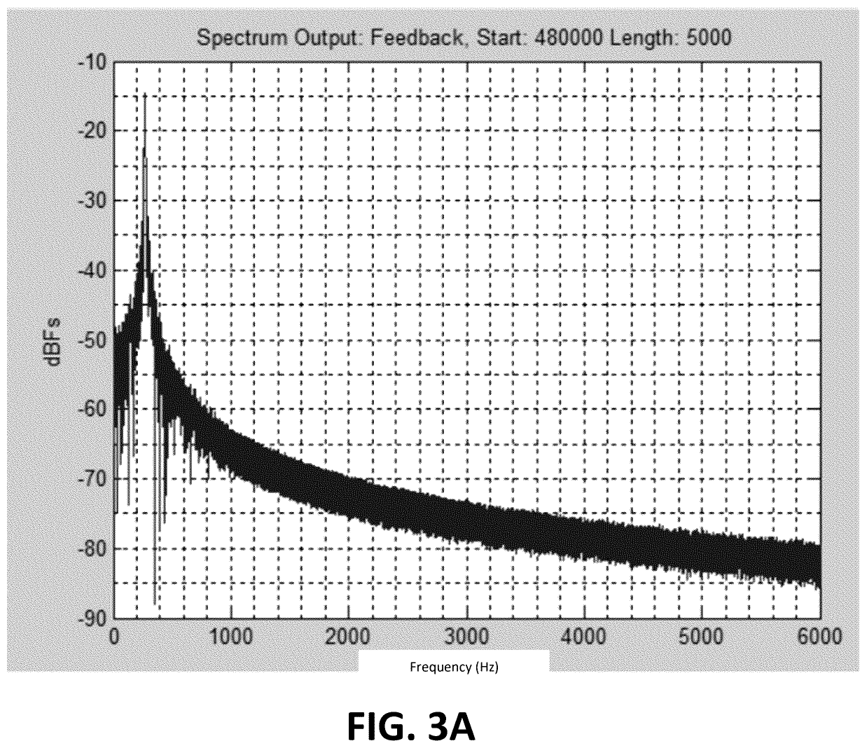

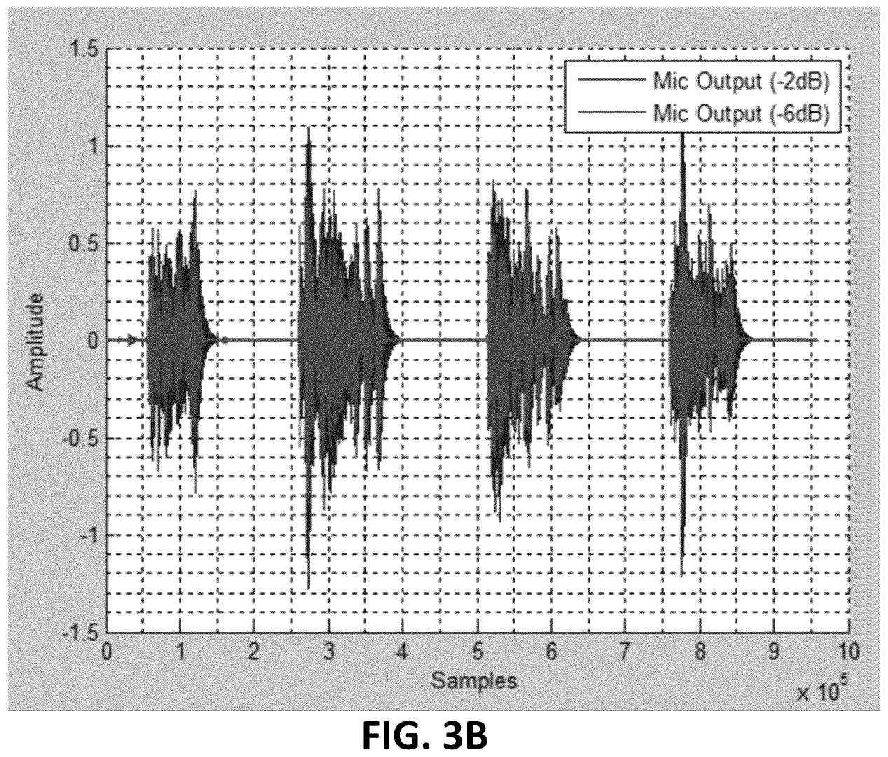

In any case, the digital audio signal and the digital reference signal may each comprise a composite (e.g. an aggregate) signal. This means that the digital audio signal and the digital reference signal may each comprise a number of individual signals, with each of these signals having different respective frequency components. In some scenarios, one or more of the signals that form the digital audio signal and the digital reference signal may include feedback. An example of the spectrum of a feedback signal is shown in FIG. 3A, which has a maximum amplitude around 280 Hz, although a maximum amplitude may occur at any other frequency for other feedback signals. An example of a pure speech signal is shown in FIG. 3B in the time domain for two different microphone gains. It is generally known that feedback signals have a very clean spectrum, whereas voiced speech typically has harmonics added from the vocal tract. More specifically, feedback signals may have a clean spectrum until a point in time at which the feedback becomes so loud that it saturates/over drives the “transducers” (e.g. speakers) in the system. At this point, the feedback signal spectrum becomes less “clean,” and therefore the detection of feedback becomes more difficult. Thus, the feedback detection techniques as further described herein may leverage the use of “full band” root mean square (RMS) power measurements to determine if the feedback spectrum is approaching a saturation scenario and may also dynamically adjust/adapt the detection thresholds used for feedback detection. In any event, when feedback is present, the digital reference signal that is used for the DFR architecture 200, as well as the digital audio signal, may each comprise a combination of a feedback signal and a voiced speech signal, with the feedback signal typically having a single fundamental frequency component and the voiced speech signal having multiple frequency components, e.g. those associated with multiple fundamental frequencies and their various harmonics.

The DFR architecture 200 may operate by first detecting the presence of feedback in the digital reference signal. As further discussed below, this is done using frequency tracking to initially identify a candidate signal that could potentially represent feedback. Then, a determination is made regarding whether a set of predefined conditions are satisfied with respect to this candidate signal. This may help ensure that feedback (e.g. one or more feedback signals) is accurately identified as part of the digital reference signal before triggering any feedback mitigation procedures, thereby reducing false detections.

To do so, the DFR architecture 200 begins via the use of the frequency tracking block 202, which may be implemented as any suitable type of filter to track the “strongest” frequency component in the digital reference signal. In other words, a candidate signal within the digital reference signal may first be determined by identifying a frequency component within the digital reference signal having a maximum energy level measurement value. The frequency tracking block 202 may thus be implemented as any suitable type of component that is configured to continuously identify the frequency of the highest amplitude signal component within the digital reference signal. In various aspects, the frequency tracking block 202 may be implemented as any suitable type of digital filter, such as a digital adaptive lattice filter for example. The frequency tracking block 202 may be configured to output frequency tracking data as well as the detected frequency of the candidate signal, e.g. the fundamental frequency component F0 of the candidate signal, as shown in FIG. 2A.

The frequency tracking block 202 may continuously and/or periodically perform the various measurements as discussed herein to identify candidate signals and output the fundamental frequency component F0 and the frequency tracking data as new digital reference signals are received over time. The rate at which the frequency tracking block 202 may perform this functionality may be a function of the architecture in which the DFR architecture 200 is implemented, the particular application, the audio sampling rate, etc. In this way, the frequency tracking block 202 may repeatedly identify the frequency component within each newly received digital reference signal having the highest energy level measurement (e.g. amplitude), as discussed above.

The isolation control block 204 may be configured to compute the filter parameters for the primary and secondary isolation filter blocks 206A, 206B. Thus, the isolation control block 204 may be configured to receive the detected frequency F0 of the candidate signal, which is used to compute any suitable filter parameters implemented by the primary isolation filter block 206A. These filter parameters may comprise, for example, the center frequency (F0), the filter bandwidth (BW), the harmonic to search for (H), etc. As further discussed below, the isolation control block 204 may also be configured to receive filter parameters from the release procedure block 216, which are then provided to the secondary isolation filter 206B and applied to a received signal associated with the digital reference signal.

For example, the DFR architecture 200 may implement the primary and secondary isolation filters 206A, 206B to extract either the higher or the lower harmonics associated with a detected candidate signal (in the case of the primary isolation filter 206A) or other received signal (in the case of the secondary isolation filter 206B), as well as an intermediate signal that is based upon the upper or lower harmonic signal. Thus, the harmonic (H) data provided by the isolation control block 204 may instruct the primary isolation filter 206A or the secondary isolation filter 206B to extract either an upper or a lower harmonic frequency. For instance, the primary and secondary isolation filter blocks 206A, 206B may be configured to extract the various frequency components associated with a received signal. To do so, the primary and secondary isolation filter blocks 206A, 206B may be implemented as any suitable type of filter, such as an adaptive isolation filter for example, which may be dynamically configured based upon the filter parameters provided by the isolation control block 204. Such adaptive filters implemented by the primary and secondary isolation filter blocks 206A, 206B may then be applied to the digital reference signal. As will be further discussed below, the primary isolation filter block 206A may be dedicated to the execution of active feedback mitigation procedures, whereas the secondary isolation block 206B may be dedicated to the execution of the feedback mitigation release procedures. The primary isolation filter block 206A and the secondary isolation block 206B may be configured as identical or substantially similar filters blocks, although each may independently output the extracted components of a respectively received signal at various times based upon the parameters received from the isolation control block 204.

The primary and secondary isolation filter blocks 206A, 206B may be implemented in accordance with any suitable adaptive filter configuration to extract any suitable number of frequency components from the digital reference signal, with three being shown in FIG. 2A as a non-limiting and illustrative example. For instance, each of the primary and secondary isolation filter blocks 206A, 206B may be implemented with any suitable number of second-order-section (SOS) sets, which may include SOS pairs. Each of the SOS pairs may thus be configured to separately extract a respective frequency component of a received signal within or otherwise associated with the digital reference signal.

Again, each of the primary and secondary isolation filter blocks 206A, 206B may be configured to extract the fundamental frequency component of a received signal within the digital reference signal, which may be a candidate signal that potentially comprises a feedback signal in the case of the primary isolation filter 206A, or other signals in the case of the secondary isolation filer 206B (such as those matching the fundamental frequency F0 used by a currently-applied notch filter for example, as further discussed below). Additionally, each of the primary and secondary isolation filter blocks 206A, 206B may be configured to selectively extract either the upper or the lower harmonic frequency component of the received signal, as instructed by the isolation control block 204, for example. Furthermore, each of the primary and secondary isolation filter blocks 206A, 206B may be configured to extract an intermediate frequency component of the received signal, which is a function of whether the upper or lower harmonic frequency component of the received signal was extracted. It is noted that the ability to evaluate the lower harmonics as well as the upper harmonics in this manner may allow for an increase in the rate of feedback detection from one-quarter of the audio sampling rate to one-half of the audio sampling rate.

Additionally or alternatively, it is noted that the operation of the DFR architecture 200 may be further modified based upon the detected fundamental frequency F0 of the received signal. To provide an illustrative example, for a frequency range in which the fundamental frequency F0 of the received signal is less than one-half of the audio bandwidth, the primary and/or the secondary isolation filter blocks 206A, 206B may be configured to track both the upper and the lower harmonics, as well as the intermediate harmonic frequency component, of the received signal to further increase detection reliability at the cost of additional processing power.

The isolation control block 204 may determine whether the primary and secondary isolation filter blocks 206A, 206B are to extract the upper or lower harmonic frequency component of the received signal based upon the fundamental frequency F0 of the received signal. This may include, for example, comparing the fundamental frequency F0 of the received signal to a predetermined threshold value, and determining whether the upper or lower harmonic frequency component of the received signal is to be extracted based upon whether the fundamental frequency F0 of the received signal is less than or greater than this predetermined frequency.

As an example, the predetermined frequency may be set to approximately half of the overall audio bandwidth of the system in which the DFR architecture 200 is implemented. Thus, for an audio bandwidth of 20 Hz to 20 kHz, the predetermined frequency threshold may be set to 10 kHz. Continuing this example, if a received signal has a fundamental frequency of 1 kHz, then the isolation control block 204 may instruct the primary and secondary isolation filter blocks 206A, 206B to extract (in addition to the fundamental frequency component of the received signal) an upper harmonic frequency component of the received signal at 2 kHz, and to extract an intermediate harmonic frequency component of the received signal between the fundamental and upper harmonic frequency, which may be approximately 1.5 kHz in this example. However, if the received signal has a fundamental frequency of 12 kHz, then the isolation control block 204 may instruct the primary and secondary isolation filter blocks 206A, 206B to extract (in addition to the fundamental frequency component of the received signal) a lower harmonic frequency component of the received signal at 6 kHz, and to extract an intermediate harmonic frequency component of the received signal between the fundamental and lower harmonic frequency, which may be approximately 9 kHz in this example.

In an embodiment, the DFR algorithm (e.g. executed via the isolation control block 204) may advantageously implement hysteresis with respect to the predetermined frequency threshold (e.g. 10 kHz in the example above) that is used to select between the upper or lower harmonics. For instance, in a scenario in which the fundamental frequency F0 is very close to this threshold limit, the DFR algorithm may prevent oscillatory behavior to avoid toggling between the computation of the upper and lower harmonics. The hysteresis frequency band selected for this purpose may represent any suitable frequency range based upon the particular application.

When hysteresis is implemented in this manner, it is noted that the sum of the predetermined frequency threshold and the upper-harmonic side hysteresis frequency range may be less than one half the supported audio bandwidth. As an example, a 20 Hz to 20 kHz system may have a predetermined frequency threshold of 8 kHz with a hysteresis frequency range of +1 kHz. This means that if the DFR algorithm is currently using upper harmonics, then the fundamental frequency F0 may, for example, go above 9 kHz to shift to the computation of lower harmonics, and vice-versa. That is, if the DFR algorithm is currently using low harmonics, then the fundamental frequency F0 may, for example, cross below 7 kHz to switch to the computation of the high harmonics.

With respect to the intermediate harmonic frequency component of the received signal, this frequency may be computed in any suitable manner, including the use of known techniques to do so. This may include, for example, computing an average value between the fundamental frequency component and a respective upper or lower harmonic frequency component. As another example, the frequency of the intermediate harmonic frequency component of the received signal may be determined using any predetermined computing process, including known processes, that function to determine the intermediate frequency within the fundamental frequency and one of the lower or upper harmonic frequencies, as discussed herein.

In any event, each of the extracted frequency components of the received signal may be provided to an RMS block 208 along with the digital reference signal, as shown in FIG. 2A. The RMS block 208 may be configured to perform any suitable type of energy level measurements on each signal that is fed to it as shown in FIG. 2A. In the example shown in FIG. 2A, the energy level measurement may comprise, for example, a root mean square (RMS) power measurement, although this is by way of example and not limitation. The RMS power measurements may alternatively be referred to herein as simply RMS values or RMS data, and may represent RMS approximations that may be computed in accordance with any suitable techniques, including known techniques. Thus, the RMS block 208 may perform a full band RMS power measurement of the digital reference signal, as well as an RMS power measurement of each extracted frequency component of the received signal output via the primary and secondary isolation filter blocks 206A, 206B. Each of these RMS values may then be stored in an RMS buffer 210, which may be configured as any suitable type and/or size of memory storage to store current RMS values as well as any suitable number of previous RMS value measurements. In this way, the RMS buffer 210 may be configured to store current and previous RMS values over any suitable window of time that may enable the feedback detection block 212 to better determine whether the candidate signal is in fact a feedback signal, for example, as well as to improve the release procedure operations, as discussed in further detail below.

In this way, the primary isolation filter block 206A may be configured to track “new” feedback frequencies having a fundamental frequency of F0 as provided by the frequency tracking block 202. The secondary isolation filter block 206B, however, may be configured to extract prior detected frequency components in accordance with the currently-applied notch filter (when applicable) that is being executed via the release procedure block 216, as discussed in further detail herein. Thus, the feedback detection block 212 may receive the current RMS values (“new RMS data”) output by the RMS block 208 with respect to a currently-measured candidate signal, as well as any suitable number of previous RMS values (“old RMS data”) with respect to previous RMS measurements of past candidate signals. In this way, the old RMS data is indicative of an energy envelope over time. The old RMS data may represent any suitable size “window” representing any suitable number of prior RMS measurements based upon the architecture in which the DFR architecture 200 is implemented, the particular application, the audio sampling rate, etc.

The feedback detection block 212 may also receive the frequency tracking data output by the frequency tracking block 202, as discussed above. To this end, it is noted that the frequency tracking block 202 may maintain frequency tracking data that indicates a history of stability with respect to the same fundamental frequency component of candidate signals being detected. In an aspect, the frequency tracking block 202 may maintain a counter with respect to each time a fundamental frequency component is detected at the same frequency, which may be defined for instance in accordance with any suitable predefined threshold value such as a 0.01% deviation, a 0.1% deviation, etc. The predefined threshold value may represent a predefined hysteresis window. As a result, the counter value may be reset each time a new, different fundamental frequency component is detected that differs in frequency from the previously detected fundamental frequency component as defined by the predefined hysteresis window. However, the counter value may be incremented each time a fundamental frequency component is detected having the same frequency as a previously detected fundamental frequency component. Thus, the frequency tracking data may comprise a counter value that represents how many continuous audio samples that the “current” candidate frequency has been unchanging, e.g. stable. In this way, if the detected fundamental frequency component of a candidate frequency starts to drift (e.g. by deviating in value by more than a predefined hysteresis window), then the counter may be reset.

The feedback detection block 212 may utilize the frequency tracking data, the old RMS data, and/or the new RMS data as shown in FIG. 2A to detect whether a current candidate signal constitutes a feedback signal. This may be done, for example, by determining whether various metrics, which are computed and/or derived from the RMS data measurements and/or the frequency tracking data, satisfy respective predetermined threshold conditions. As further discussed below, the feedback detection block 212 may implement any suitable combination of these various conditions being satisfied in accordance with their respective metrics to determine whether the candidate signal comprises feedback in the digital reference signal.

One example condition that may be considered by the feedback detection block 212 to detect feedback may comprise the current RMS values of a fundamental frequency component of the candidate signal (e.g. the “absolute” level of the fundamental frequency component) satisfying a corresponding predetermined threshold energy value. This may be the case, for example, when the new RMS data indicates that the RMS values of a fundamental frequency component of the candidate signal meet or exceed a predetermined threshold RMS value. The predetermined threshold RMS value may be determined, for example, based upon any suitable information, such as known system information in which the DFR architecture 200 is implemented and/or the anticipated energy levels of the digital reference signal. By using this as one possible condition to be satisfied to detect feedback, it may be better ensured that the candidate signal is not part of a voice signal but exceeds the expected range of RMS values of the digital reference signal.

Another example condition that may be considered by the feedback detection block 212 to detect feedback may comprise a plurality of previous energy level measurements of the fundamental frequency component of the candidate signal over a time interval satisfying a corresponding predetermined threshold energy value. This may be the case, for example, when the old RMS data indicates that the previous RMS values of a fundamental frequency component of the candidate signal meet or exceed a predetermined threshold RMS value. This determination may implement any suitable metrics, statistical data, etc., with respect to previous (e.g. “old”) RMS values. For example, the previous RMS values of a fundamental frequency component of the candidate signal may comprise a total energy envelope RMS value, an average RMS value, a maximum RMS value, a median RMS value, etc. As an illustrative example, the total energy envelope RMS value of the fundamental frequency component of the candidate signal may be computed as a ratio calculation of old RMS values to new RMS values, with the number of old and new RMS values representing any suitable number of respective RMS measurements within any suitable respective time periods and/or samples. Thus, the calculation of the total energy envelope RMS value in this manner may be particularly useful for a determination regarding whether a feedback signal is decreasing, stable, or increasing, as discussed in further detail below. In any event, the corresponding predetermined threshold energy value may be satisfied, for example, when the previous RMS values of a fundamental frequency component of the candidate signal meet or exceed the predetermined threshold RMS value. By requiring that this condition be satisfied to detect feedback, it is ensured that the candidate signal RMS value is not transient in nature, but has been persistently present in the digital reference signal during a specific window of time.

Another example condition that may be considered by the feedback detection block 212 to detect feedback may comprise the stability of the fundamental frequency of the candidate signal over a predetermined time period satisfying a corresponding predetermined threshold value. The stability may be computed by the feedback detection block 212 based upon the counter value that is included as part of the frequency tracking data. Thus, the stability of the fundamental frequency of the candidate signal may be expressed in terms of a counter value that represents a number consecutive candidate signals having a fundamental frequency at the same frequency. The predetermined threshold value may thus be satisfied for instance when this counter value meets or exceeds a corresponding threshold counter value.

Another example condition that may be considered by the feedback detection block 212 to detect feedback may comprise the current RMS values of a harmonic frequency component of the candidate signal (e.g. the “absolute” level of the harmonic frequency component) satisfying a corresponding predetermined threshold energy value. Again, the frequency of the harmonic frequency component that is used for this purpose may comprise an upper or a lower harmonic component of the fundamental frequency of the candidate signal based upon whether the fundamental frequency is greater than or less than a predefined frequency, as noted above. This may be the case, for example, when the new RMS data indicates that the RMS value of the harmonic frequency component of the candidate signal meets or exceeds a predetermined threshold RMS value.

Another example condition that may be considered by the feedback detection block 212 to detect feedback may comprise the current RMS values of an intermediate frequency component of the candidate signal (e.g. the “absolute” level of the intermediate frequency component) satisfying a corresponding predetermined threshold energy value. The intermediate frequency component may represent any suitable frequency that is between the fundamental frequency and the harmonic frequency (which may be an upper or a lower harmonic frequency) for the candidate signal, as noted above. The feedback detection block 212 may determine that this condition is met, for example, when the new RMS data indicates that the RMS value of the intermediate frequency component of the candidate signal meets or exceeds a predetermined threshold RMS value.

Still further, other example conditions that may be considered by the feedback detection block 212 to detect feedback may comprise other metrics that are computed from the various data inputs as shown in FIG. 2A and discussed above. As one example, a condition may comprise a ratio of an RMS value of the intermediate frequency component of the candidate signal (as described above) to the harmonic RMS value of the candidate signal. As another example, a condition may comprise a ratio of an RMS value of the fundamental frequency component of the candidate signal to a harmonic RMS value of the candidate signal. In accordance with such scenarios, the feedback detection block 212 may determine that such conditions are met, for example, when the new RMS data indicates that this ratio, in either case, meets or exceeds a predetermined ratio value.

Again, the feedback detection block 212 may use any combination of the aforementioned conditions being met to determine that the candidate signal comprises feedback in the digital reference signal. This may include, for example, all of the conditions being met or any subset of these conditions being met. These conditions have been provided by way of example and not limitation, and the feedback detection block 212 may utilize any suitable additional or alternate conditions to detect the presence of feedback in the digital reference signal.

The feedback detection block 212 may be configured to output, using any of the aforementioned conditions or combinations thereof, data that is indicative of the presence and nature of any detected feedback in the digital reference signal. For instance, and as shown in FIG. 2A, the feedback detection block 212 may output a feedback detected flag, a frequency stable flag, and a high level feedback flag. The feedback detection block 212 may output additional or alternate information with respect to any detected feedback.

With continued reference to FIG. 2A, the feedback detected flag may represent a binary indication of whether the candidate signal comprises feedback within the digital reference signal based upon any combination of the various conditions being met as discussed above. The feedback detected flag thus indicates whether or not the current candidate signal comprises feedback based upon this binary value. In other words, the feedback detected flag indicates whether feedback is currently detected within the digital reference signal.

The frequency stable flag may represent a binary value that indicates whether the current candidate signal is stable at a particular frequency. The frequency stable flag may be used in various ways. For example, in some aspects, the feedback detection block 212 may utilize the stability of the fundamental frequency F0 of the candidate signal to determine whether the candidate signal represents feedback, as noted above. However, in other aspects, the feedback detection block 212 may utilize other conditions to determine that the candidate signal represents feedback within the digital reference signal even when fundamental frequency is unstable. This allows the DFR architecture 200 additional flexibility in how to apply the feedback mitigation techniques, which are discussed in further detail below. That is, the feedback detection block 212 may determine that the candidate signal represents feedback within the digital reference signal, but the frequency of this feedback is unstable, e.g. has drifted over time. Thus, the frequency stability flag is used to instruct the mitigation procedure block 214 whether to deploy a notch filter (via the notch filter block 220) or to alternatively apply a system gain reduction (via system gain block 218).

The high level flag may represent any suitable encoded value that may classify and/or define the level of the detected feedback in the digital reference signal. For example, the RMS values as discussed above with respect to the fundamental, harmonic, and/or intermediate frequency components of the candidate signal may be compared to a set of thresholds. One of these (e.g. the lowest threshold value) may be used for feedback detection, whereas other (e.g. higher values) may be used to further classify the severity of the detected feedback. Any suitable number of thresholds may be used for this purpose, and thus the high level flag is not limited to a binary value but instead may represent any suitable encoded value that conveys this information to the mitigation procedure block 214. For example, the high level flag may indicate to the mitigation procedure block 214 to act more aggressively in removing feedback by adjusting the configuration of the notch filters block 220 and/or the system gain block 218, which is discussed in further detail below.

As shown in FIG. 2A, each of the outputs of the feedback detection block 212 may be provided to the mitigation procedure block 214, together with the fundamental frequency F0 of the candidate signal that is output by the frequency tracking block 202. Thus, the mitigation procedure block 214 may be configured to utilize these inputs to execute a feedback mitigation procedure to reduce feedback in the digital audio signal in response to the detection of feedback within the digital reference signal via the feedback detection block 212. The feedback detection block 212 may execute any suitable number and/or type of feedback mitigation procedures to attempt to reduce or eliminate the presence of any detected feedback from the digital audio signal.

As one example, the feedback mitigation procedure block 214 may include applying one or more suitable filters, such as notch filters for example, to the digital audio signal at a notch frequency corresponding to that of the fundamental frequency component F0 of the candidate signal. To do so, the mitigation procedure block 214 may track the feedback detection flag together with the high level flag and the frequency stability flag to apply a notch filter at the fundamental frequency F0 of the candidate signal. Upon receiving an indication that feedback is detected via the feedback detected flag, the mitigation procedure block 214 may transmit configuration data to the notch filters block 220, which may comprise information regarding the filter parameters for the notch filter(s) that are to be applied.

The filter parameters may comprise, for example, the depth of the notch filter, which may be selected by the mitigation procedure block 214 depending on the severity/loudness of the feedback, which may be identified via the high level flag and/or by accessing the RMS value for the fundamental frequency component of the candidate signal. The mitigation procedure block 214 may also transmit the configuration data to the notch filters block 220 to make an already existing notch filter block deeper (e.g. provide further attenuation/damping over a defined notch filter bandwidth, provide further attenuation/damping at the notch filter frequency, etc.) if feedback continues to persist at a certain frequency (e.g. based upon a threshold number of previous mitigation procedures at the same frequency being exceeded). The mitigation procedure block 214 may also transmit the configuration data to the notch filters block 220 to make an existing notch filter wider (e.g. increase the notch filter bandwidth) if the feedback appears close to the center frequency of a currently-applied filter.

Thus, the filter parameters that may be transmitted as part of the configuration data to the notch filters block 220 may comprise for example the center frequency of the notch filter, a gain setting (e.g. an attenuation/damping value) a depth of the notch filter, a bandwidth of the notch filter, a shape and/or roll off, etc. The bandwidth of the notch filter(s) may be a function of the fundamental frequency component F0 of the candidate signal, for example. It is noted that the mitigation procedure block 214 may have access to the RMS values stored in the RMS block 208 and the RMS buffer 210, which may also include the corresponding frequencies of the harmonic and intermediate frequency components of the candidate signal that were extracted via the primary isolation filter block 206A, as noted above. The mitigation procedure block 214 may use this frequency data to determine the bandwidth of the notch filter(s) to be applied via the notch filters block 220 to ensure that the notch filter has the appropriate width.

As another example, the feedback mitigation procedure may include reducing a gain applied to the digital audio signal. This may include, for example, reducing the full-band system gain. This option may be particularly useful, for example, if it is determined by the mitigation procedure block 214 that feedback continues to occur despite applying several notch filters and/or when the frequency stable flag indicates an unstable feedback frequency. To do so, the mitigation procedure block 214 may transmit configuration data to the system gain block 218, which may comprise information regarding the system gain parameters for example. For instance, the system gain parameters may comprise an amplifier gain setting and/or a corresponding gain level that may be applied to the digital audio signal by the audio system 100 in which the DFR architecture 200 is implemented.

It is noted that the mitigation procedure block 214 may transmit the configuration data to the notch filters block 220 and the system gain block 218, which may update their respective gains. However, to ensure that the audio quality is maintained and to avoid anomalies such as pops, hisses, etc., the notch gain smoothing block 222 may be configured to run independently of the mitigation procedure block 214 and to control the configuration of the notch filters block 220 and the system gain block 218. This may include, for instance, ramping the current gain of the notch filters block 220 and the system gain block 218 towards the current target gain setting determined by the mitigation procedure block 214 on a per sample basis.

Again, the mitigation procedure block 214 may determine the particular configuration of the notch filters block 220 and/or the system gain block 218 based upon the data output by the feedback detection block 212, which includes the high level flag. To this end, the mitigation procedure block 214 may adjust the configuration settings based upon previous and/or current conditions of the detected feedback. For instance, feedback detection block 212 may detect the early onset of feedback with a low RMS value at the fundamental frequency, which may trigger the mitigation procedure block 214 to initially apply a “softer” configuration setting to the notch filters block 220 and/or the system gain block 218. This may include a lower gain/attenuation setting, a shallower notch (e.g. less attenuation/damping over a defined notch filter bandwidth, provide less attenuation/damping at the notch filter frequency, etc.), a wider notch filter frequency, etc. However, the opposite may be true for a scenario in which feedback is detected later, has persisted for a longer period of time, and/or has a higher RMS value at the fundamental frequency. In such a case, the mitigation procedure block 214 may then apply a more “aggressive” configuration setting to the notch filters block 220 and/or the system gain block 218 to remove the feedback much faster. In this way, the high level flag may for instance enable the mitigation procedure block 214 to provide different configurations for the notch filters block 220 and/or the system gain block 218, which may reflect the aggressiveness of the feedback mitigation procedure depending on the level of the feedback.

Moreover, it is noted that the notch filters block 220 and/or the system gain block 218 may be separate blocks that may be detached from other blocks (e.g. the frequency tracking block 202, the feedback detection block 212, etc.) in DER architecture 200. For instance, the audio pipeline 103 as discussed herein may include an audio chain, which is used to receive audio signals from audio devices (e.g. microphones) that are then processed in accordance with the various DFR techniques as discussed herein to provide signals to other audio devices (e.g. speakers), as discussed above with respect to FIG. 1. The audio chain may thus comprise, for example, the audio signal input block 203, the notch filters 220, the system gain block 218, the audio output block 230, as well as any suitable type of audio processing blocks that are typically identified with such an audio chain.

The other components of the DFR architecture 200 as shown in FIG. 2A may also form part of the audio pipeline 103 or other suitable component, but may form part of a reference audio chain that is used for the analysis as discussed herein with respect to the various DFR techniques. For instance, the frequency tracking block 202 and the feedback detection block 212 may not be in the audio chain, but may be part of this reference audio chain. The components of the audio chain and the reference audio chain need not be placed proximate to one another depending on the system in which the DFR architecture 200 is implemented. This makes it possible to select where in the audio chain the feedback should be addressed while running the frequency tracking and detection at a separate location. This may be particularly useful, for instance, when multiple inputs are used in a single output system in which the inputs are manual or automixed into one output channel. In this case, the frequency tracking block 202 and the feedback detection block 212 may be placed at the location of the common output signal, but the feedback mitigation procedures (e.g. the notch filter and/or or system gain reduction) may be applied to the specific input that is causing the feedback. That is, in a multiple output system, the feedback mitigation may only be applied to the output channel that is used for sound-reinforcement, and not to other output channels that terminate elsewhere (e.g. recording, far-end/another room). This is further discussed below with respect to FIG. 2B.

Once any of the feedback mitigation procedures have been applied to the digital audio signal as discussed above with respect to FIG. 2A, an adjusted digital audio signal may be provided to the audio output block 230. The audio output block 230 may then output the adjusted digital audio signal as an output audio signal. The audio output block 230 may be identified with any suitable stage in the audio pipeline 103, which may include an intermediate stage or the output of the audio pipeline 103 for instance. When used as an output of the audio pipeline 103, the output audio signal may be transmitted to the audio device 102, which may comprise a speaker for example. Thus, the audio output block 230 may, for instance, be optionally identified with the conversion of a received adjusted digital audio signal to provide an analog audio signal, which may then be provided to the audio device 103 for example as discussed above. The output audio signal may thus be provided to a speaker for example, at a corresponding system port.

As discussed above, the DFR architecture 200 may include applying the feedback mitigation procedures via the notch filters block 220 and/or the system gain block 218 upon detecting the presence of feedback in the digital reference signal. The DFR architecture 200 may also include the automatic triggering of a release procedure, which aims to reverse the feedback mitigation procedures as discussed above when the feedback is no longer detected. To do so, the release procedure block 216 may also receive the feedback detected flag output by the feedback detection block 212 as noted above. Additionally, the release procedure block 216 may receive the old and new RMS data values as discussed above with respect to the feedback detection block 212, and may use these data inputs to determine whether to execute a release procedure that discontinues the current execution of the feedback mitigation procedure as discussed herein.

In various embodiments, the release procedure block 216 may be triggered using any suitable RMS values, which may represent RMS measurements with respect to any of the outputs of the primary isolation filter block 206A and/or the secondary isolation filter block 206B. However, it may be particularly useful for the release procedure block 216 to utilize the RMS measurements with respect to the outputs of the secondary isolation filter block 206B, as this allows for operation of the release procedures using separate and independent RMS measurements during the execution of the feedback mitigation procedures, as noted herein.

To provide an illustrative example, the release procedure block 216 may receive both the old and the new RMS values output via the secondary isolation filter block 206B, which may be accessed via the RMS block 208 and/or the RMS buffer 210. The release procedure block 216 may then determine whether the energy level of a fundamental signal component output via the secondary isolation filter 206B has an increasing or a decreasing trend based upon a comparison between a current energy level, as indicated by the new RMS values and the previous signal energy levels, as indicated by the old RMS values. Then, for an example scenario in which the signal energy level is not decreasing, while all other metrics remain satisfied (e.g. the current signal energy level remains below a predetermined threshold value), the release procedure block 216 may determine that a release procedure is to be initiated.

It is also noted that any suitable subset or combination of metrics may be utilized to trigger the initiation of the release procedure, which may be the same as those discussed above with respect to feedback detection in the candidate signal. However, such metrics may be with respect to the old and new RMS values corresponding to the outputs of the secondary isolation filter block 206. Of course, the specific conditions used to trigger a release procedure, as well as the predetermined threshold value(s) used for this purpose, may be different than those used to detect the presence of feedback.

In any event, the release procedure block 216 may perform this functionality independently of the mitigation procedure block 214. As a result, the release procedure block 216 may be configured to determine whether to initiate a release procedure concurrently with the current execution of any feedback mitigation procedures instructed by the mitigation procedure block 214. To do so, the release procedure block 216 may use the feedback detected flag indicating the absence of feedback (which may be mitigated via the ongoing feedback mitigation procedures) as a trigger to begin executing the release procedure. Thus, it is noted that the feedback detection block 212 may detect feedback in the candidate signal in accordance with any combination of the aforementioned conditions noted above, which are with respect to the RMS values of the frequency components of the candidate signal output via the primary isolation filter 206A. However, the release procedure block 216 may analyze the RMS values with respect to the frequency components of the received signal output via the secondary isolation filter 206B.

Thus, the release procedure block 216 may use any of the aforementioned conditions implemented by the feedback detection block 212 to detect the presence of feedback in a received signal, but may instead do so with respect to the RMS values of the frequency components of the received signal output via the secondary isolation filter 206B. For example, and as discussed in further detail below, the release procedure block 216 may configure the parameters of the secondary isolation block 206B via communications with the isolation control block 204. These parameters may cause the secondary isolation filter 206B to extract the various harmonic components of a received signal to match the frequency component(s) of interest for any given notch filter that is presently-applied by the notch filters block 220 that is attempted to be removed.

This may be determined, for instance, based on a predetermined period of time being exceeded during which new feedback detections have not occurred (e.g. as detected via the feedback detection block 212). To provide an illustrative example, if a currently-applied notch filter has a center frequency of 1 kHz, the release procedure block 216 may control the isolation control block 204 to configure the secondary isolation block 206B to filter out the fundamental 1 kHz frequency, the upper harmonic 2 kHz frequency, and an intermediate harmonic frequency of approximately 1.5 kHz from the digital reference signal. The release procedure block 216 may be configured, for example, to then monitor those levels and ratios (RMS approximations) over a predetermined time period to justify whether a mitigation process may be initiated by releasing the notch filter (e.g. in small predetermined increments) while continuing to monitor the levels and ratios (RMS approximations) for the above-referenced frequencies. Any indication of feedback within those frequencies, as well as any indication of a new detected feedback frequency, may mean that release procedure block 216 reverts to its previous step, during which it once again waits for the duration of another predetermined time period before attempting to perform the release procedure again.

However, the release procedure block 216 may also utilize the feedback detected flag output by the feedback detection block 212 as part of the release procedure process. For instance, if the feedback detected flag indicates that feedback is detected, even though the feedback is occurring at a different frequency than that measured via the release procedure block 216, then the release procedure block 216 may pause any current release activities until the feedback detected flag indicates that no feedback is present. Thus, the release procedure block 216 may utilize the feedback detected flag to trigger a release procedure attempt when it indicates that no feedback has been detected, as well as to pause a currently-executed release procedure when the feedback detected flag indicates that feedback has returned. In doing so, the release procedure block 216 may independently analyze and test whether the currently-applied notch filters may be removed again without re-introducing the feedback. Again, the DFR architecture 200 may implement a separate secondary isolation filter block 206B for this purpose, which may be configured identical or substantially similar to the primary isolation filter 206A as discussed above.

The isolation control block 204 may thus function to independently control each of the primary and secondary isolation filters 206A, 206B. That is, the isolation control block 204 may control the configuration of the primary isolation filter 206A in accordance with a center frequency that is determined from the frequency tracking block 202 as the fundamental frequency F0 of the candidate signal. However, the isolation control block 204 may control the configuration of the secondary isolation filter 206B based upon the center frequency of the notch filter currently applied via the notch filters block 220. That is, the secondary isolation filter block 206B may apply, to the digital reference signal, an isolation filter having filter parameters that are based upon filter parameters of the applied notch filter. That is, the secondary isolation filter block 206B may provide a center frequency matching that used by one of the notch filters, which has been applied to the digital audio signal. As the release procedure block 216 continues to remove notch filters, the parameters used by the secondary isolation filter block 206B are then updated via the isolation control block 204 to match the next notch filters that that are to be removed. As a result, it is possible for the center frequency used by the primary and secondary isolation filters 206A, 206B to be different than one another. This may be the case, for example, when a newly received candidate signal has a fundamental frequency F0 that differs from the previous one, e.g. the one currently implemented as the notch filter center frequency via the notch filters block 220.

Moreover, by implementing these two separate and independent isolation filter blocks, any buildup of energy at the designated frequencies (fundamental, harmonic, intermediate, etc.) may be detected immediately and in parallel with any potential new feedback detection. The release procedure block 216 may be configured to optionally monitor the RMS levels of the candidate signals at these designated frequencies over time and to perform a full band level decay time analysis of the candidate signals to evaluate the “hotness” of the digital reference signal. This may be performed, for instance, using any combination of the new RMS data and the old RMS as discussed herein, with the computed metrics being compared to a predetermined threshold value.

As an illustrative example, assuming that the feedback detected flag indicates no current feedback, if the measured RMS values are less than respective threshold values, then the release procedure block 216 may be configured to execute a release procedure. In this example, this may include reducing the depth of a currently-applied notch filter, which is then followed by a time period during which the same metrics (e.g. the RMS values) are evaluated continuously to check for any significant changes in the feedback as a result of the reduced notch filter depth. For instance, the release procedure block 216 may monitor the feedback detected flag and the new RMS data measurements associated with the frequency components extracted via the secondary isolation filter block 206B during the release procedure execution. In doing so, the release procedure block 216 may be configured to determine whether feedback will remain in the digital audio signal if the feedback mitigation procedure is stopped.

To do so, the release procedure block 216 may, for example, compare one or more RMS value measurements of the frequency components output by the secondary isolation filter block 206A for a subsequently-received candidate signal to respective threshold energy levels. Thus, if the level of any of these RMS value measurements exceed a threshold value, the release procedure block 216 may determine that the release procedure is to be aborted, as doing so may potentially increase the feedback level. In this scenario, the release procedure block 216 may be configured to skip or abort the release procedure attempt and to revert the deepness of the currently-applied notch filter.

The release procedure block 216 may also be configured to store a history of such failed attempts to prevent repeated attempts to perform the release procedure under similar conditions. To provide an illustrative example, the release procedure may function in a “round robin” style. That is, if the measured metrics of the outputs of the secondary isolation filter block 206B at one point in time satisfy a predetermined release condition, then the release procedure block 216 may initiate a partial (e.g. step) release of a specific notch filter or system gain. The release procedure block 216 may then subsequently consider, one step at a time, these same metrics to determine if the predetermined condition is still met. If a step-wise release of a particular mitigation block (e.g. a reduced applied notch filter or a reduced system gain) is successful, that notch depth or new system gain setting may then become a new “target value,” and the release procedure may attempt to execute this same process for the next mitigation block in the line (e.g. in a reverse order in which the notch filter or system gain was applied as part of the mitigation procedures or in accordance with any suitable predetermined order). If unsuccessful at any step, then that particular step may be canceled (e.g. reverted to the initial, pre-step notch depth and/or system gain setting), and the release procedure block 216 may then proceed to attempt to execute this process for the next mitigation block in the line.

Embodiments include the release procedure block 216 accessing and/or maintaining any suitable time-based reference to facilitate the release procedures as discussed herein. This time-based reference may, for example, comprise a timer that periodically generates a timer signal in accordance with the expiration of an adjustable time period, which may also be referred to herein as a timer value. This time period represents how long time the system may be actively used before the release procedure block 216 attempts to initiate a release procedure. The time period may be dynamically updated based upon the system conditions. For instance, during periods of silence and/or idle time periods, the time period may not be adjusted and remain at a prior and/or predetermined value, whereas the history of previous release procedures and the results of these release procedures may be used to adjust this time period.

To provide an illustrative example, a successful or a non-successful release procedure attempt may result in an adjustment to the timer value, which again may provide an indication of how much time should pass (e.g. as a minimum) before a particular mitigation block can be examined again. In this way, continuous failed attempts may quickly lengthen the time period of the timer, whereas successful attempts result in a shortening of the time period of the timer. This mechanism may prevent the DFR algorithm from continuing to perform release procedures for current mitigation procedures that are needed to prevent feedback from re-occurring, and may also allow for a fast dynamic adjustment to fully releasing a mitigation block if circumstances have changed.

The notch filters block 220 may be configured to apply any suitable number of notch filters to the digital audio signal based upon a history of different detected frequencies via the feedback detection block 212. For example, the feedback detection block 212 may detect feedback at different frequencies over time, and the mitigation procedure block 214 may provide configuration data to the notch filters block 220 as feedback is detected at each of these frequencies. The number of notch frequencies that the notch filters block 220 may concurrently apply to the digital audio signal in this manner may be a function of the DFR architecture 200, the device in which the DFR architecture 200 is implemented, the particular application, etc.

Again, the embodiments as discussed herein may include the release procedure block 216 releasing the currently-applied notch filters in various ways based upon different types of information such as the RMS measurements, the feedback detected flag, etc. In various embodiments, the manner in which the notch filters are released may be performed in different ways, which may include releasing all filters at once (e.g. in accordance with the round robin scheme as further discussed herein), or in a sequential manner. In any event, the determination of which notch filters are released and/or the order of their release may utilize any suitable number and/or type of conditions, including those discussed above. Such conditions may include, for instance, the number of currently-applied notch filters, the status of the currently-applied notch filters, whether feedback is detected at a new frequency that is different than a previous frequency used to apply the current set of notch filters, etc. Embodiments may thus include the release procedure block 216 releasing the notch filters currently applied by the notch filters block 220 in a sequential order based upon a predetermined prioritization scheme or, alternatively and as discussed herein, via a round-robin selection scheme.

To provide an illustrative example of a sequential notch filter release procedure, the release procedure block 216 may determine that feedback still exists (via the feedback detected flag) despite all available notch filters currently being deployed. In such a case, the release procedure block 216 may prioritize one of these notch filters to be released, which may then be replaced with a new notch filter at the detected new feedback frequency, which may be configured via the mitigation procedure block 214. To do so, as one example the release procedure block 216 may identify which of the currently-applied notch filters is the “shallowest” (e.g. the filter with the least amount of attenuation/damping) from among the currently-applied notch filters. Then, the release procedure block 216 may provide configuration data to the notch filters block 220 to release this shallowest currently-applied notch filter. This may be the case, for instance, when feedback at a new frequency is detected that differs from the previously-detected frequencies used to apply the current set of notch filters.

This sequential release procedure thus allows the mitigation procedure block 214 to provide updated configuration data to the notch filters block 220 to replace the shallowest applied notch filter with a new filter having a new filter configuration to mitigate the detected feedback. This may serve as an “emergency” or “immediate” release function, which attempts to mitigate currently detected feedback by releasing the notch filter from the currently-applied notch filter set that is likely to have the least amount of mitigating impact on removing feedback from the digital audio signal. Again, doing so may facilitate an additional notch filter being made available as soon as the feedback is detected, with the mitigation procedure block 214 then facilitating the application of a new notch filter at the new feedback frequency in its place.

Additionally or alternatively, the release procedure block 216 may use time-based conditions to determine the prioritization of releasing a currently-applied notch filter. For instance, after immediately releasing a shallowest applied notch filter, the release procedure block 216 may then rank, group, categorize, etc., the remaining currently-applied notch filters in accordance with any suitable thresholding system. Such thresholds may be with respect to maximum attenuation/damping (e.g. the “bottom” of the notch filter) or any other suitable metric that may be used to classify the “strength” of each currently-applied notch filter. The release procedure block 216 may then select, from among the group of shallowest currently-applied notch filters, those notch filters that have been in use for the longest time, the shortest time, etc.

As noted above, the release procedure block 216 may maintain any suitable time-based reference to facilitate the release procedures as discussed herein. This time-based reference may comprise a single timer for the application of all applied notch filters such that the release procedure block 216 references a single timer to determine when to initiate a new release procedure with respect to all applied notch filters, which may be referred to as a “global” timer. Additionally or alternatively, the release procedure block 216 may maintain a “per-notch” filter timer. Thus, the release procedure block 216 may reference the per-notch filter timer as discussed herein to identify how long each notch filter has been applied, which may then be leveraged to as part of the prioritization of releasing a currently-applied notch filter, as discussed above.

For instance, upon detecting feedback at a new frequency while all notch filters are deployed, the release procedure block 216 may release the currently-applied notch filters in a reverse order in which they were first applied, such that the oldest applied notch filters may be retained, as this likely represents stable and persistent feedback that is less likely to be a false detection. These time-based conditions may be used in conjunction with the other prioritization conditions discussed herein or independently of such conditions. For example, the use of such time-based prioritization release schemes may occur after the shallowest filter is detected and released as noted above, and then implemented to determine a prioritization that is applied to the remaining notch filters as additional feedback frequencies are detected. Alternatively, the time-based prioritization release schemes may be used independently of the other conditions discussed herein such that the release prioritization is based upon the time (e.g. exclusively based on the time) in which each currently-applied notch filter has been deployed.

Although not shown in the Figures for purposes of brevity, the release procedure block 216 may also utilize additional or alternate inputs to determine whether to execute the release procedure. For example, such inputs may enable the release procedure block 216 to execute a release procedure based upon one or more external inputs that are indicative of a change in a system state that potentially impacts the generation of the digital reference signal. To provide some examples, the system state may comprise moving a portion of the system in which the DFR architecture 200 is implemented (e.g. one or more microphones), docking information indicating that a device has been docked, accelerometer inputs from microphones, impulse response changes offered by an acoustic echo cancellation (AEC) or other suitable alternative algorithms, etc.

For example, accelerometers in connected microphones may generate sensor data indicative of whether a microphone that is currently causing feedback is suddenly moving, which may be processed via a processing component of the system in which the DFR architecture 200 is implemented. An indication of this microphone movement may then be transmitted to the release procedure block 216, which may use this input as one of the conditions that, when met, results in the execution the release procedure. As another example, similar impulse response changes in a microphone causing feedback may be a good indication for triggering the release procedure. Impulse changes monitoring may be available, for instance, in hybrid systems in which there is both sound-reinforcement and a far-end participant requiring local acoustic echo cancelation. Other means of talker tracking may also be implemented for this purpose, for example to track the movement of a person holding the microphone through acoustic, radar, video, or other sensory data for instance.

Additionally or alternatively, by leveraging the RMS value measurements associated with the frequency components extracted by the secondary isolation filter block 206B, the release procedure block 216 may evaluate various environmental conditions without the need to rely on external sensor inputs. For instance, by analyzing current and previous RMS values, the release procedure block 216 may approximate the reverberation of a room by measuring the signal “drop” time when active audio is followed by silence. By using a set of predetermined profiles, the release procedure block 216 may determine whether a change in the environment has occurred by way of changes in the reverberation pattern, and that the room conditions have been evaluated as “safe” to try to start a release procedure.

Again, the DFR architecture 200 as shown in FIG. 2A may comprise additional, fewer, or alternate functional blocks as those shown and discussed herein. Thus, the DFR architecture 200, as well as the DFR techniques that may be implemented in accordance with the DFR architecture 200, may be modified depending upon the particular use case, architecture, computing platform, desired application, etc. To this end, a DFR architecture 250 is shown in FIG. 2B, which may include several variations compared to the DFR architecture 200 as shown in FIG. 2A. It is noted that the variations as shown and discussed with respect to the DFR architecture 250 in FIG. 2B are provided by way of example and not limitation, and aspects may be realized based upon any suitable combination of the different variations as shown in FIG. 2B. For instance, the DFR architecture 200 may be modified in accordance with each of the variations as discussed herein with respect to the DFR architecture 250 or, alternatively, any subset of such variations may be implemented. As another example, any suitable portion (or the entirety of) the DFR architecture 200 may be duplicated to run multiple instances thereof instead of the use of the DFR architecture 250. This may be particularly useful, for instance, when implemented as part of a multiple input/output system.

For instance, the RMS buffer 210 may be integrated as part of the RMS block 258 as shown in FIG. 2B. Thus, the RMS buffer 210 and the RMS block 258 may constitute a single functional block, which may represent a single integrated component for example. Such implementations may be particularly advantageous to reduce the number of internal connections and/or to increase the speed at which RMS values are stored. As further discussed below, the RMS block 258 may additionally or alternatively perform different RMS power measurements compared to the RMS block 208 based upon the particular inputs that are received.

To this end, it is noted that the DFR architecture 250 may receive multiple audio signals, with each audio signal being identified with a different audio source (e.g. a different microphone). Additionally, one or more of the audio signals may comprise a multi-channel (e.g. mixed) audio signal. Thus, the digital reference signal and the digital audio signal as discussed above with respect to FIG. 2A may each comprise a multi-channel signal, or may be signals that are part of a larger set of input audio signals, as discussed in further detail below. Thus, the DFR architecture 250 may be adapted to a multi-channel and/or multi-source audio system. For example, the DFR architecture 250 may receive a mixed audio reference signal and a mixed audio path input signal, which may be analogous to the digital reference signal and the digital audio signal, respectively, as discussed with respect to the DFR architecture 200.

And as discussed above with respect to the DFR architecture 200, the mixed audio reference signal and the mixed audio path input signal may likewise represent the same signal or be identified with different blocks within the audio pipeline 103. For example, the mixed audio reference signal input block 251 may be identical or similar to the reference signal input block 201 as discussed above, and may thus represent a reference input port, which provides the digital reference signal as the audio sample that is received via the DFR architecture 250 and used to extract audio signal information that is used in accordance with the various DFR techniques as discussed herein. The digital reference signal as shown in FIG. 2B, however, may comprise a mixed (e.g. multi-channel) signal.

Additionally, the mixed audio path input block 253 may be identical or similar to the audio signal input block 203 as discussed above, and may represent a separate audio input port that provides the digital audio signal. The digital audio signal may represent a live or raw audio sample, to which the notch filters and system gain may be applied before the audio is sent to the next stage within the audio pipeline 103. The digital audio signal as shown in FIG. 2B, however, may also comprise a mixed (e.g. multi-channel) signal. The mixed audio reference signal input port (block 251) and the mixed audio path input port (block 253) may be identified with the same location and/or stage or a different location and/or stage within the audio pipeline 103. In this way, the use of two ports may facilitate a DFR process that provides flexibility and allows for the adaptation to different audio chain architectures.

Additionally or alternatively, the DFR architecture 250 may comprise any suitable number of frequency tracking blocks 202 and isolation filters 206A, 206B. Thus, although the same number of frequency tracking blocks 202 and isolation filters 206A, 206B are shown in FIG. 2B as those shown in FIG. 2A, this is by way of example and not limitation. To concurrently track multiple feedback signals, the DFR architecture 250 may include multiple frequency tracking blocks 202, and each may concurrently track a separate respective candidate signal. To do so, each one of the multiple frequency tracking blocks 202 may be configured to operate over a different frequency spectrum and/or to identify candidate signals meeting different criteria. For instance, a first frequency tracking block 202 may be configured to identify a first component of the digital reference signal having a maximum energy component, whereas a second frequency tracking block 202 may be configured to identify a second component of the digital reference signal having a second-highest maximum energy component, and so on. Thus, for each additional frequency tracking block 202, the DFR architecture 250 may comprise an additional primary and secondary isolation filter 206A, 206B. The use of additional frequency tracking blocks 202 and isolation filters 206A, 206B may be particularly advantageous, for instance, when the digital reference signal comprises a multi-channel signal, as feedback may exist at different frequencies among the different individual channels.

Each frequency tracking block 202 may operate in the same manner as discussed above with respect to the DFR architecture 200. However, additionally or alternatively, the frequency tracking data may be transmitted directly to the mitigation procedure block 264, which may operate in a similar manner as the mitigation procedure block 214. Thus, the frequency tracking data may also be processed by the mitigation procedure block 264 in addition to the feedback detection block 212. This modification may enable the frequency detection block 212 to still utilize the frequency tracking data to detect feedback, which is indicated by the feedback detected flag as shown in FIG. 2B. However, the mitigation procedure block 264 may locally determine from the frequency tracking data whether the feedback is stable instead of the feedback detection block 212 performing this determination as discussed above for the DFR architecture 200. Thus, the frequency stable flag is no longer output via the frequency detection block, offloading this processing functionality to the mitigation procedure block 264.

Again, the DFR architecture 250 may receive additional digital audio signals and digital reference signals, which may comprise multi-channel signals or other types of audio signals, such as the audio signals as caused above with respect to FIG. 2A. This is illustrated in additional detail with respect to FIGS. 2B and 2C. For instance, FIG. 2C shows an additional audio source path signal 1:x, which is a multi-channel signal that is received via block 282. A corresponding reference signal is shown in FIG. 2B as the audio source reference signal 1:x, which is received via the block 255. The audio source path signal 1:x and the corresponding audio source reference signal 1:x may represent the same signal or be identified with different blocks within the audio pipeline 103.

FIG. 2B illustrates an audio source path reference signal block 255, which may be identical or similar to the mixed audio reference signal input block 251 as discussed above. Furthermore, FIG. 2C illustrates an audio source path in block 282, which may be identical or similar to the mixed audio path input block 253 as discussed above. Thus, the digital reference signal associated with the mixed audio reference signal input block 251 may be associated with (e.g. the same signal or signals sampled from different stages within the audio pipeline 103) as the digital audio signal associated with the mixed audio signal input block 253. Furthermore, the digital reference signals associated with the audio source reference signal block 255 may be associated with (e.g. the same signal or signals sampled from different stages within the audio pipeline 103) as the digital audio signal associated with the audio source path block 282 as shown in FIG. 2C.

Thus, the DFR architecture 250 may support performing DFR techniques in accordance with any suitable number of audio signals, each being associated with a respective reference signal. Each audio signal and accompanying reference signal may constitute any suitable type of audio signal, which may be a single channel signal or a multi-channel signal, as discussed herein. Regardless of the number and type of digital audio signals that may be present in a given audio system, any of the feedback mitigation procedures as discussed above with respect to FIG. 2A may be implemented for each signal. As a result, for each signal to which the feedback mitigation procedures are applied, an adjusted digital audio signal may be provided to the mixed audio path output block 280 and/or the audio source path output block 290 as shown in FIGS. 2B and 2C, as the case may be.

The mixed audio path output block 280 and/or the audio source path output block 290 may output the adjusted digital audio signal as an output audio signal. The mixed audio path output block 280 and the audio source path output block 290 may be identical or similar to the audio output block 230 as discussed with respect to FIG. 2A, and thus may be identified with any suitable location in the audio pipeline 103, which may include an intermediate stage or the output of the audio pipeline 103. Again, when used as an output of the audio pipeline 103, the output audio signal may be transmitted to the audio device 102, which may comprise a speaker. Thus, the audio path output block 280 and the audio source path output block 290 may, for instance, optionally be identified with the conversion of a received adjusted digital audio signal to provide an analog audio signal, which may be provided to the audio device 103 for example as discussed above. The output audio signal may thus be provided to a speaker for example, at a corresponding system port. For a multi-channel signal, the audio signal output via the audio path output block 280 and the audio source path output block 290 may comprise a single channel or a multi-channel signal, with the latter being illustrated in the Figures as a non-limiting example.

As shown in FIG. 2B, the audio source reference signal 1:x may be decomposed into x channels via the audio source mix gain block 256. The channel decomposition data (x channels) is transmitted to the RMS block 258, which may perform a per-channel RMS value measurement. The RMS block 258 may also receive the digital reference signal, and may perform a full band RMS power measurement. The full band RMS measurement may represent current RMS values, as well as any suitable number of previous RMS values, and may be performed in the same manner as the full band RMS measurement value measurements as discussed above with respect to FIG. 2A. The mixed audio path decomposition block 260 may receive the per-channel RMS value measurement as well as the full band RMS measurements. The mixed audio path decomposition block 260 may for example use this information to provide channel decomposition data. The channel decomposition data may thus represent any of the RMS value measurements and feedback identification measurements as discussed above with respect to the DFR architecture 200, but on a per-channel basis in accordance with the channel decomposition data. In other words, the mixed audio path decomposition block 260 may provide channel decomposition data to the control output 270 that identifies the RMS measurements for each of the x channels, as well as a full band RMS measurements across all x channels.

Thus, the channel decomposition data may be provided to the channel output control block 270. The channel output control block 270 may process this data to indicate any information regarding the audio system to any suitable user interface. The data output by the channel output control block 270 may be transmitted in accordance with any suitable format and/or protocol that is recognized by any suitable user interface, such as a graphical user interface (GUI) that may translate this information using any suitable techniques to be presented in a visual form. This may include, for example, which audio inputs are the cause of feedback, the level of feedback, a description of the feedback and any currently-applied mitigating procedures, etc.

In this way, when used in accordance with a multiple input, multiple output audio system, the DFR architecture 250 may advantageously track which audio inputs are actually causing the feedback, and the channel decomposition information may be utilized by the mitigation procedure block 264 and the release procedure block 266 to determine whether specific feedback sources need to be addressed. Such independent control may be particularly useful to prevent an unnecessarily application of feedback mitigating procedures, for example when a particular microphone input is muted and thus not responsible for causing the detected feedback. In other words, the DFR architecture 250 may enable a post-mix solution in which the audio inputs are monitored from all potential audio inputs and, by analyzing their input and RMS measurements, the DFR architecture 250 may track which one is actually causing the feedback.

The channel decomposition data may also be provided to the release procedure block 266 and the mitigation procedure block 264, which may operate in a similar manner as their analogous counterpart components as shown in FIG. 2A, e.g. the release procedure block 216 and the mitigation procedure block 214. However, and turning now to FIG. 2C, the DFR architecture 250 may include a separate notch filters block 284 and a system gain block 286, which may be controlled by the release procedure block 266 and the mitigation procedure block 264 separately and independently from the notch filters block 220 and the system gain block 218. The notch filters block 284 and the system gain block 286 may operate in the same manner as the notch filters block 220 and the system gain block 218, although the notch filters block 284 and the system gain block 286 may be coupled to the additional audio source path input block 282. The notch filters block 284 and the system gain block 286 may utilize RMS value measurements from a second set of primary and secondary isolation filters, as noted above. Alternatively, the notch filters block 284 and the system gain block 286 may utilize RMS value measurements from the primary isolation filter 206A and the secondary isolation filter 206B, with each channel sharing the same set of filters in a time-division duplexing manner. In this way, by using the channel decomposition information, the release procedure block 266 and the mitigation procedure block 264 may apply feedback mitigation and release procedures to separate audio input signals.

Additionally or alternatively, the DFR architectures 200, 250 may comprise any suitable number of separate release procedures and secondary isolation filters 206B. For instance, the release procedure block 216 as shown in FIG. 2A and/or the release procedure block 266 as shown in FIGS. 2B and 2C may be identified with any suitable number of separate release procedures, each using the RMS data measurements from a dedicated secondary isolation filter 206B. These embodiments may be particularly useful, for instance, for implementations that are not MIPS constrained.

It is noted that the notch filters block 284 and the system gain block 286 may operate as separate and independent processing blocks with respect to the notch filters block 220 and the system gain block 218. In other words, each of the notch filters block 220, the notch filters block 284, the system gain block 218, and the system gain block 286 may comprise separate signal processing blocks that may be detached from main DFR architecture 250 signal processing blocks (e.g. the frequency tracking block 202, the primary and secondary isolation filter blocks 206A, 206B, the feedback detection block 212, etc.).

Again, the DFR architectures 200, 250 may be implemented as a part of any suitable system, which may be identified with, for example, any suitable portion of the audio system 100 as discussed herein. Thus, the DFR architectures 200, 250 may be implemented as a part of one of the audio devices 101, 102 and/or the audio pipeline 103, as discussed herein. As one example, the DFR architectures 200, 250 may be implemented as part of any suitable type of wireless audio receiver, wireless audio transmitter, wireless audio transceiver, etc. (which may be part of the audio devices 101, 102 and/or the audio pipeline 103 or separate devices). Such wireless audio receiver, wireless audio transmitter, wireless audio transceiver, etc., may be implemented as part of a wireless microphone system for instance. Thus, any of the DFR algorithms as discussed herein may likewise be performed as part of such a wireless microphone system and/or as part of a wireless audio receiver, wireless audio transmitter, wireless audio transceiver, etc., which may be implemented as part of such a wireless microphone system or other suitable system.

As another example, the DFR architecture 200 and/or 250 may be implemented as part of an aggregation device or other suitable device in which multiple inputs are used in a single output system, with the inputs are being manually or automixed into one output channel. Thus, the DFR architecture 200 and/or 250 may utilize an “automixed” input and/or output in accordance with such implementations. Such automixed audio signals may include, for instance, the input to the mixed audio path input block 253, the input to the audio source path in block 282, the output of the mixed audio path output block 280, the output of and/or the audio source path output block 290, etc., as shown in FIGS. 2B and 2C, as the case may be.

Examples of aggregation devices in which the DFR architectures 200, 250 may be implemented to function as discussed herein may include any suitable type of microphone device. Such a microphone device may include a microphone array having any suitable number of microphones. Thus, in accordance with such an implementations, a contribution of an automixed output may include, for instance, a number of microphone inputs or beamforming lobes, which may be gated on/off depending on their input activity. Continuing this example, the automixed input signal that is received by any of the blocks of the DFR architectures 200, 250 (e.g. the notch filters block 220 and/or 282) may change its characteristics depending on which microphone or beamforming lobe is included/gated in the currently automixed signal.

Further continuing this example, any of the blocks of the DFR architectures 200, 250 implemented in conjunction with such an aggregation device may advantageously obtain information regarding how automixed signals are constructed to adapt any suitable number and/or type of parameters used in accordance with their respective operations. This information may be referred to herein as “signal construction information.” Thus, any of the blocks of the DFR architectures 200, 250 as discussed herein may communicate with and/or otherwise receive such signal construction information from any suitable components within the audio pipeline in which they are implemented. This may include, for instance, data that is received from the aggregation device, which may be included as part of the reference signal or, alternatively, as a separate data communication (not shown).

For instance, in response to the signal construction information, the mitigation procedure block 264 may update the configuration data and transmit the updated configuration data to the notch filters block 220, which again may comprise information regarding the filter parameters for the notch filter(s) that are to be applied to the digital (e.g. automixed) signal. This updated configuration data may cause the notch filters block 220 to adapt the currently applied notch filters to reflect how the currently received automixed signal is created. For example, one beamforming lobe out of a set of lobes may be causing the feedback. Thus, although the notch filters block 220 may employ any suitable number of notch filters on a mixed signal generated from all lobes, the information received via the audio pipeline may advantageously enable the mitigation procedure block 264 to determine that specific lobes are causing feedback at different frequencies and at different severities. Thus, the mitigation procedure block 264 may adapt the filter parameters for the notch filter(s) implemented via the notch filters block 220 using this information. Although the use of the information received via the audio pipeline in this way may be implemented by the mitigation procedure block 264 in this example, this (as well as other suitable information) may be implemented by any of the blocks of the DFR architectures 200, 250 to adapt their functionality over time.

For example, the feedback detection block 212 may adjust any of the thresholds discussed herein with respect to the various predetermined threshold conditions used to detect feedback, the threshold counter values, etc., based upon the signal construction information. To provide additional examples, the mitigation procedure block 264 may modify the type of mitigation that is performed and/or the manner the mitigating procedures are performed as discussed herein based upon the signal construction information. To provide yet another example, the release procedure block 266 may adapt the manner (e.g. order of notch filters being released, the release scheme, etc.) in which the release procedure is performed based on the signal construction information.

Again, an example of the spectrum of a feedback signal 300 is shown in FIG. 3A. The feedback signal as shown in FIG. 3A may be identified with a candidate signal as noted herein that has been identified as a feedback signal using any of the feedback detection techniques and conditions as described herein. An example of a pure speech signal 350 is also shown in FIG. 3B in the time domain for two different microphone gains. The feedback signal 300 and the speech signal 350 may each constitute part of the digital reference signal and the digital audio signal as described above with respect to FIGS. 2A-2C. Thus, when it is assumed that feedback is present, the digital reference signal and the digital audio signal may each comprise a combination of the feedback signal 300 and the voiced speech signal 350.

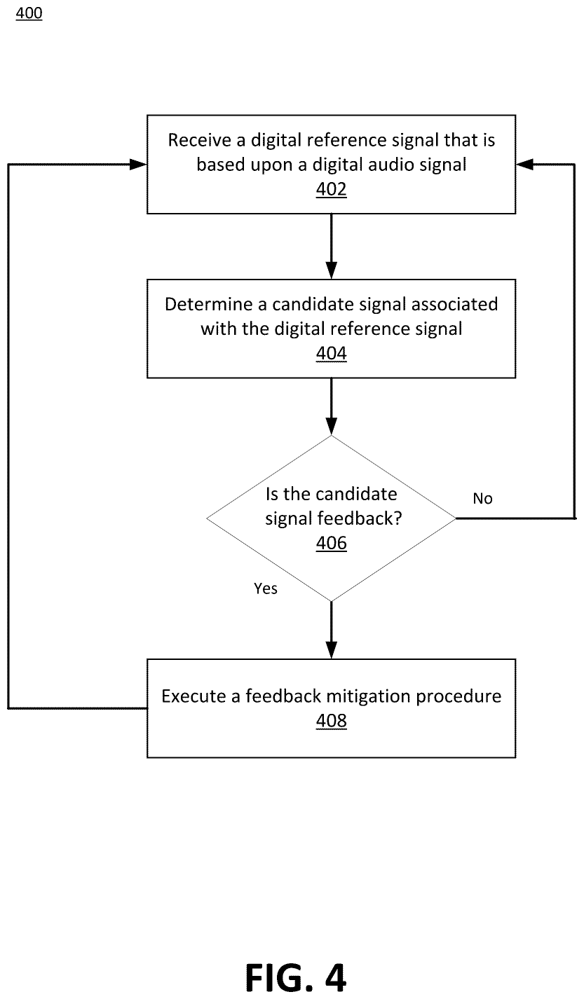

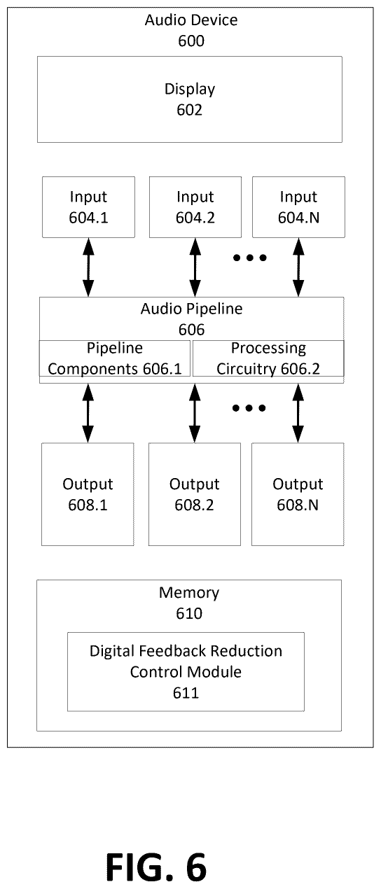

FIG. 4 illustrates an example flow chart of a method that may be performed to implement one or more illustrative aspects described herein. The flow 400 may comprise a portion of the DFR architecture 200 as discussed herein with respect to FIGS. 2A-2C. The flow 400 may comprise a process flow that is executed by and/or otherwise associated with one or more processors and/or components identified with any suitable electronic device. The electronic device may comprise, for example, any suitable portion of and/or device identified with the audio pipeline 103 as discussed above with respect to FIG. 1. The one or more processors and/or components may be identified for example with those implemented by such an electronic device, e.g. the electronic device 600 as discussed in further detail below. The flow 400 may thus may be implemented via the processing circuitry 606.2 as discussed herein with respect to FIG. 6 executing instructions stored on any suitable computer-readable storage medium, such as the memory 610. The flow 400 may include alternate or additional processes that are not shown for purposes of brevity, and may be performed in a different order than those shown.

Flow 400 may begin by receiving (block 402) a digital reference signal that is based upon a digital audio signal, as discussed above with respect to the DFR architecture 200.

The flow 400 may further comprise determining (block 404) a candidate signal that is associated with the digital reference signal. This may include, for example, identifying a frequency component of the digital reference signal having a maximum energy level measurement value.

The process flow 400 may then continue to determine (block 406) whether the candidate signal constitutes feedback in the digital reference signal. This may be determined, for instance, via any of the conditions mentioned above with respect to the feedback detection block 212. If not, then the flow 400 may return to the initial step, during which the next digital reference signal is received (block 402).

However, if feedback is detected (block 406), then the flow 400 may proceed to execute (block 408) a feedback mitigation procedure. This may include, for instance, any of the feedback mitigation procedures discussed above with respect to the mitigation procedure block 214. For instance, a notch filter at the fundamental frequency of the detected feedback may be applied to the digital audio signal and/or a system gain may be reduced, etc. Upon executing the feedback mitigation procedure, the flow 400 may again return to the initial step, during which the next digital reference signal may be received (block 402).

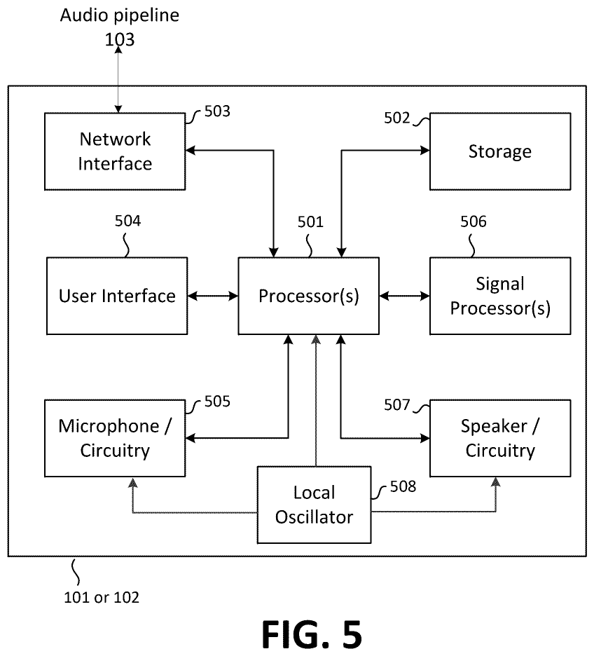

FIG. 5 is a block diagram showing example details of an audio device that may be part of an audio system, such as the audio system of FIG. 1. For example, the audio device may be the audio device 101 or the audio device 102. The audio device may be implemented as or may otherwise include, for example, a computing device that executes stored instructions, and/or as hard-wired circuitry and or one or more processors may execute stored computer-readable instructions. In the shown example, the computing device may comprise or be connected to any of the following: one or more processors 501, storage 502 (which may comprise one or more computer-readable media such as memory), an external interface such as a network interface 503 (which may be configured to communicate with a network and/or the audio pipeline 103), a user interface 504, one or more microphones and/or associated elements 505 configured to detect sound and convert that detected sound into an audio signal such as analog audio signal or a digital audio signal, one or more digital signal processors 506 configured to implement one or more digital signal processing features of the audio device, one or more speakers and/or associated elements 507 configured to produce sound in response to a received audio signal such as an analog audio signal or a digital audio signal, and/or a local oscillator 508. The one or more processors 501 may be communicatively connected to any of the other elements 502-508 via one or more data buses and/or via one or more other types of connections.

The circuitry of elements 505 and 507 may be separate circuitry or a single instance of combined circuitry, as desired. In the shown example, the local oscillator 508 may provide the local asynchronous media clock signal to the one or more processors 501, the circuitry of element 505, and the circuitry of element 507. However, the local asynchronous media clock signal may be provided to any of the elements of FIG. 5, as desired. In an example, the one or more processors 501 may receive a signal from the local oscillator 508, and the one or more processors 501 may generate the asynchronous local media clock based on the signal from the local oscillator 508. For example, the one or more processors 501 may comprise phase-locked loop (PLL) circuitry, and the signal from the local oscillator 508 may be an input to (e.g., for driving) the PLL circuitry.

The one or more processors 501 may be configured to execute instructions stored in storage 502. The instructions, when executed by the one or more processors 501, may cause the computing device (and thus the audio device) to perform any of the functionality described herein that is performed by the audio device (such as the audio device 101 or the audio device 102). For example, the one or more processors 501 may control the operation of any of the other elements 502-508 of the audio device, and/or may direct various signals (such as audio signals and/or clock signals) amongst the various elements 502-508 of the audio device.

Power may be provided to the audio device and/or to any of the elements of the audio device (e.g., any of the elements 501-508) as desired. While not explicitly shown, the audio device may include an internal battery and/or an external power connection.

FIG. 6 is a block diagram showing example details of an audio device that may be part of an audio system, such as the audio system of FIG. 1 for example. The electronic device 600 may be identified with any suitable type of electronic device in an audio pipeline, such as the audio pipeline 103 as discussed with respect to FIG. 1 for instance. Thus, the electronic device 600 may be identified with a rackmount or portable electronic device, a user equipment (UE), any suitable type of computing device such as a laptop computer, a desktop computer, a server, a cloud computing platform, etc.

The electronic device 600 may comprise a display 602. The display 602 may be implemented as or form part of any suitable type of display assembly such as a light-emitting diode (LED) display, a liquid crystal display (LCD), an organic LED display, a Twisted Nematic (TN) display, an In-Plane Switching (IPS) display, etc. The display 602 may be configured to display information regarding feedback within the audio system in which the DFR architecture 200 is implemented, as discussed above. For instance, the display 602 may present information provided by the control output block 270 as shown and discussed with respect to the DFR architecture 250.

The electronic device 600 may comprise any suitable number N of inputs 604.1-604.N. Each of the inputs 604.1-604.N may be identified with an audio source that is received by the audio pipeline 103 as discussed herein, and may be identified with any of the audio inputs as shown in FIGS. 2A-2C. The audio inputs 604.1-604.N may be coupled to and/or receive audio signals in analog or digital form from any suitable audio device, such as the audio devices 101, 102 as discussed herein.

The electronics device 600 may further comprise an audio pipeline 606, which may receive the audio signals via the inputs 604.1-604.N. The audio pipeline 606 may comprise pipeline components 606.1 and processing circuitry 606.2. The pipeline components 606.1 may comprise any suitable number of audio stages and audio components that may form part of the DFR architectures 200, 250, and may be controlled and/or monitored as part of the DFR processes as discussed herein with respect to FIGS. 2A-2C. For example, the audio pipeline 606 may comprise ADCs, DACs, gain adjusters, hardware-based filters, the various functional blocks as discussed herein, etc.

The processing circuitry 606.2 may be configured as any suitable number and/or type of computer processors, and which may function to control the electronic device 600 and/or other components of the electronic device 600, such as the various DFR processes as discussed herein. The processing circuitry 606.2 may be identified with one or more processors (or suitable portions thereof) implemented by the electronic device 600. The processing circuitry 606.2 may be identified with one or more processors such as a host processor, a microcontroller, a digital signal processor, one or more microprocessors, a central processing unit (CPU), graphics processors such as a graphics processing unit (GPU), baseband processors, microcontrollers, an application-specific integrated circuit (ASIC), part (or the entirety of) a field-programmable gate array (FPGA), etc.

The processing circuitry 606.2 may be configured to carry out instructions to perform arithmetical, logical, and/or input/output (I/O) operations, and/or to control the operation of one or more components of electronic device 600 to perform various functions as described herein. The processing circuitry 606.2 may include one or more microprocessor cores, memory registers, buffers, clocks, etc., and may generate electronic control signals associated with the components of the electronic device 600 to control and/or modify the operation of these components. The processing circuitry 606.2 may communicate with and/or control functions associated with the memory 610, as well as any other components of the electronic device 600. Thus, the processing circuitry 606.2 may control or cause other components to detect and mitigate detected feedback, as well as initiate release procedures, as discussed herein.

The electronic device 600 may comprise any suitable number N of outputs 608.1-608.N. Each of the outputs 608.1-608.N may be identified with an audio output of the audio pipeline 606 as discussed herein, and may be identified with any of the audio outputs as shown in FIGS. 2A-2C or any other stage within the audio pipeline 606. The audio inputs 604.1-604.N may be coupled to and/or send audio signals in analog or digital form to any suitable audio device, such as the audio devices 101, 102 as discussed herein.

The memory 610 may be configured to store data and/or instructions such that, when executed by the processing circuitry 606.2, may cause the electronic device 600 to perform various functions as discussed herein with respect to the DFR processes of FIGS. 2A-2C. The memory 610 may be implemented as any suitable type of volatile and/or non-volatile memory, including read-only memory (ROM), random access memory (RAM), flash memory, a magnetic storage media, an optical disc, erasable programmable read only memory (EPROM), programmable read only memory (PROM), etc. The memory 610 may be non-removable, removable, or a combination of both. The memory 610 may be implemented as a non-transitory computer readable medium storing one or more executable instructions such as logic, algorithms, code, etc. The instructions, logic, code, etc., stored in the memory 610 are represented by the various modules as shown. The processing circuitry 606.2 may execute the instructions stored in the memory 610, which are represented as the various modules and further discussed below, to enable any of the techniques as described herein with respect to the various DFR processes to be functionally realized.

The digital feedback reduction control module 611 may store computer-readable instructions that, when executed by the processing circuitry 606.2, may enable the processing circuitry 606.2 to perform any of the various DFR processes as described herein with respect to received audio signals. Thus, the processing circuitry 606.2 may execute the instructions stored in the digital feedback reduction control module 611 to control, monitor, and/or regulate the operation of the electronic device 600, analyze received audio signals, determine candidate signals, determine whether feedback is present, determine if and how to perform feedback mitigating procedures, determine if and when to perform releasing procedures, etc.

An example method may comprise receiving a composite digital reference signal that is based upon the digital audio signal; detecting feedback within the composite digital reference signal based on: an energy level measurement of a fundamental frequency component of a candidate signal of the composite digital reference signal satisfying a first predetermined threshold energy value, and a plurality of previous energy level measurements of the fundamental frequency component of the candidate signal over a time interval satisfying a second predetermined threshold energy value; and executing, based upon detecting the feedback within the composite digital reference signal, a feedback mitigation procedure to reduce the feedback in the digital audio signal. The feedback mitigation procedure comprises at least one of: applying a notch filter to the digital audio signal at a notch frequency corresponding to that of the fundamental frequency component of the candidate signal, or reducing a gain applied to the digital audio signal. The composite digital reference signal may comprise the digital audio signal. The method may further comprise, after executing the feedback mitigation procedure, executing a release procedure to discontinue execution of the feedback mitigation procedure by sequentially releasing one or more of a set of notch filters currently applied to the digital audio signal. The releasing the one or more of the set of notch filters currently applied to the digital audio signal may be based upon an attenuation value provided by each of the set of notch filters. The candidate signal may be determined by identifying a frequency component of the composite digital reference signal having a maximum energy level measurement value. The method may further comprise extracting, via an isolation filter, the fundamental frequency component of the candidate signal; selectively extracting, via the isolation filter based upon a frequency of the fundamental frequency component of the candidate signal, an upper-harmonic frequency component or a lower-harmonic frequency component of the candidate signal having an upper harmonic frequency and a lower harmonic frequency, respectively; and extracting, via the isolation filter, an intermediate frequency component of the candidate signal having a frequency that is (i) between the frequency of the fundamental frequency component and the upper harmonic frequency when the upper-harmonic frequency component is extracted, or (ii) between the frequency of the fundamental frequency component and the lower harmonic frequency when the lower-harmonic frequency component is extracted. The feedback within the composite digital reference signal may be detected further based upon an energy level measurement of the intermediate frequency component of the candidate signal and one of (i) the upper-harmonic frequency component, or (ii) the lower-harmonic frequency component. The feedback within the composite digital reference signal may be detected further based upon based upon a computation of: a ratio of an energy level measurement of a fundamental frequency component to a harmonic energy level measurement value of the candidate signal, a ratio of an energy level measurement of the intermediate frequency component of the candidate signal to a harmonic energy level measurement value of the candidate signal, and a stability of a fundamental frequency of the fundamental frequency component of the candidate signal over a predetermined time period. The method may further comprise: after executing the feedback mitigation procedure, executing a release procedure to discontinue execution of the feedback mitigation procedure based upon one or more external inputs being indicative of a change in a system state that potentially impacts generation of the digital reference signal. The feedback mitigation procedure may comprise applying a notch filter to the digital audio signal at a notch frequency corresponding to that of the fundamental frequency component of the candidate signal, and the method may further comprise: concurrently with executing the feedback mitigation procedure, determining whether to initiate a release procedure to discontinue execution of the feedback mitigation procedure by: applying, to the composite digital reference signal, an isolation filter having filter parameters that are based upon filter parameters of the applied notch filter; and determining whether feedback will remain in the audio signal if the feedback mitigation procedure is stopped by comparing one or more energy level measurements of frequency components output by the isolation filter of a further candidate signal to respective threshold energy levels. The composite digital reference signal and the digital audio signal may each comprises a multi-channel signal.

An example non-transitory computer-readable medium may comprise one configured to store instructions thereon that, when executed by one or more processors, cause the one or more processors to perform adaptive feedback reduction in a digital audio signal by: detecting feedback within a composite digital reference signal that is based upon the digital audio signal based on: an energy level measurement of a fundamental frequency component of a candidate signal of the composite digital reference signal satisfying a first predetermined threshold energy value, and a plurality of previous energy level measurements of the fundamental frequency component of the candidate signal over a time interval satisfying a second predetermined threshold energy value; and executing, based upon detecting the feedback within the composite digital reference signal, a feedback mitigation procedure to reduce the feedback in the digital audio signal. The feedback mitigation procedure comprises at least one of: applying a notch filter to the digital audio signal at a notch frequency corresponding to that of the fundamental frequency component of the candidate signal, or reducing a gain applied to the digital audio signal. The composite digital reference signal may comprise the digital audio signal. The instructions, when executed by one or more processors, may further cause the one or more processors to, after executing the feedback mitigation procedure, execute a release procedure to discontinue execution of the feedback mitigation procedure by sequentially releasing one or more of a set of notch filters currently applied to the digital audio signal. The releasing the one or more of the set of notch filters currently applied to the digital audio signal may be based upon an attenuation value provided by each of the set of notch filters. The instructions, when executed by one or more processors, may further cause the one or more processors to determine the candidate signal by identifying, as the candidate signal, a frequency component of the composite digital reference signal having a maximum energy level measurement value. The instructions, when executed by one or more processors, further cause the one or more processors to: extract, via an isolation filter, the fundamental frequency component of the candidate signal; selectively extract, via the isolation filter based upon a frequency of the fundamental frequency component of the candidate signal, an upper-harmonic frequency component or a lower-harmonic frequency component of the candidate signal having an upper harmonic frequency and a lower harmonic frequency, respectively; and extract, via the isolation filter, an intermediate frequency component of the candidate signal having a frequency that is (i) between the frequency of the fundamental frequency component and the upper harmonic frequency when the upper-harmonic frequency component is extracted, or (ii) between the frequency of the fundamental frequency component and the lower harmonic frequency when the lower-harmonic frequency component is extracted. The feedback within the composite digital reference signal may be detected further based upon an energy level measurement of the intermediate frequency component of the candidate signal and one of (i) the upper-harmonic frequency component, or (ii) the lower-harmonic frequency component. The feedback within the composite digital reference signal may be detected further based upon a computation of: a ratio of an energy level measurement of a fundamental frequency component to a harmonic energy level measurement value of the candidate signal, a ratio of an energy level measurement of the intermediate frequency component of the candidate signal to a harmonic energy level measurement value of the candidate signal, and a stability of a fundamental frequency of the fundamental frequency component of the candidate signal over a predetermined time period. The instructions, when executed by one or more processors, further cause the one or more processors to: after executing the feedback mitigation procedure to reduce feedback in the digital audio signal, execute a release procedure to discontinue execution of the feedback mitigation procedure based upon one or more external inputs being indicative of a change in a system state that potentially impacts generation of the digital reference signal. Executing the feedback mitigation procedure may comprise applying a notch filter to the digital audio signal at a notch frequency corresponding to that of the fundamental frequency component of the candidate signal, and the instructions, when executed by one or more processors, further cause the one or more processors to: concurrently with executing the feedback mitigation procedure, determining whether to initiate a release procedure to discontinue execution of the feedback mitigation procedure by: applying, to the composite digital reference signal, an isolation filter having filter parameters that are based upon filter parameters of the applied notch filter; and determining whether feedback will remain in the audio signal if the feedback mitigation procedure is stopped by comparing one or more energy level measurements of frequency components output by the isolation filter of a further candidate signal to respective threshold energy levels. The composite digital reference signal and the digital audio signal may each comprises a multi-channel signal.

In the foregoing specification, the present disclosure has been described with reference to specific exemplary examples thereof. Although the invention has been described in terms of a preferred example, those skilled in the art will recognize that various modifications, examples or variations of the invention can be practiced within the spirit and scope of the invention as set forth in the appended claims. The specification and drawings are, therefore, to be regarded in an illustrated rather than restrictive sense. Accordingly, it is not intended that the invention be limited except as may be necessary in view of the appended claims.

Unless otherwise specified, the use of the serial adjectives, such as, “first,” “second,” “third,” and the like that are used to describe components, are used only to indicate different components, which can be similar components. But the use of such serial adjectives is not intended to imply that the components must be provided in given order, either temporally, spatially, in ranking, or in any other way.

Also, while the terms “front,” “back,” “side,” and the like may be used in this specification to describe various example features and elements, these terms are used herein as a matter of convenience, for example, based on the example orientations shown in the figures and/or the orientations in typical use. Nothing in this specification should be construed as requiring a specific three dimensional or spatial orientation of structures in order to fall within the scope of the claims.

Although examples are described above, features and/or steps of those examples may be combined, divided, omitted, rearranged, revised, and/or augmented in any desired manner. Various alterations, modifications, and improvements will readily occur to those skilled in the art. Such alterations, modifications, and improvements are intended to be part of this description, though not expressly stated herein, and are intended to be within the spirit and scope of the disclosure. Accordingly, the foregoing description is by way of example only, and is not limiting.

1. A method for performing adaptive feedback reduction in a digital audio signal, comprising:
receiving a composite digital reference signal that is based upon the digital audio signal;
detecting feedback within the composite digital reference signal based on:
an energy level measurement of a fundamental frequency component of a candidate signal of the composite digital reference signal satisfying a first predetermined threshold energy value, and
a plurality of previous energy level measurements of the fundamental frequency component of the candidate signal over a time interval satisfying a second predetermined threshold energy value; and
executing, based upon detecting the feedback within the composite digital reference signal, a feedback mitigation procedure to reduce the feedback in the digital audio signal.

2. The method of claim 1, wherein the executing the feedback mitigation procedure comprises at least one of:
applying a notch filter to the digital audio signal at a notch frequency corresponding to that of the fundamental frequency component of the candidate signal, or
reducing a gain applied to the digital audio signal.

3. The method of claim 1, further comprising:
after executing the feedback mitigation procedure, executing a release procedure to discontinue execution of the feedback mitigation procedure by sequentially releasing one or more of a set of notch filters currently applied to the digital audio signal.

4. The method of claim 3, wherein the releasing the one or more of the set of notch filters currently applied to the digital audio signal is based upon an attenuation value provided by each of the set of notch filters.

5. The method of claim 1, further comprising:
determining the candidate signal by identifying a frequency component of the composite digital reference signal having a maximum energy level measurement value.

6. The method of claim 1, further comprising:
extracting, via an isolation filter, the fundamental frequency component of the candidate signal;
selectively extracting, via the isolation filter and based upon a frequency of the fundamental frequency component of the candidate signal, either an upper-harmonic frequency component of the candidate signal having an upper harmonic frequency, or a lower-harmonic frequency component of the candidate signal having a lower harmonic frequency; and
extracting, via the isolation filter, an intermediate frequency component of the candidate signal having a frequency that is: (i) between the frequency of the fundamental frequency component and the upper harmonic frequency when the upper-harmonic frequency component is extracted, or (ii) between the frequency of the fundamental frequency component and the lower harmonic frequency when the lower-harmonic frequency component is extracted.

7. The method of claim 6, wherein the detecting the feedback within the composite digital reference signal is further based upon an energy level measurement of the intermediate frequency component of the candidate signal and one of: (i) the upper-harmonic frequency component, or (ii) the lower-harmonic frequency component.

8. The method of claim 1, wherein the detecting the feedback within the composite digital reference signal is further based upon a computation of:
a ratio of an energy level measurement of a fundamental frequency component of the candidate signal to a harmonic energy level measurement value of the candidate signal,
a ratio of an energy level measurement of an intermediate frequency component of the candidate signal to a harmonic energy level measurement value of the candidate signal, and
a stability of a fundamental frequency of the fundamental frequency component of the candidate signal over a predetermined time period.

9. The method of claim 1, further comprising:
after executing the feedback mitigation procedure, executing a release procedure to discontinue execution of the feedback mitigation procedure based upon one or more external inputs being indicative of a change in a system state that impacts a generation of the digital reference signal.

10. The method of claim 1, wherein the executing the feedback mitigation procedure comprises applying a notch filter to the digital audio signal at a notch frequency corresponding to that of the fundamental frequency component of the candidate signal, and
wherein the method further comprises:
concurrently with executing the feedback mitigation procedure, determining whether to initiate a release procedure to discontinue execution of the feedback mitigation procedure by:
applying, to the composite digital reference signal, an isolation filter having filter parameters that are based upon filter parameters of the applied notch filter; and
determining whether feedback will remain in the audio signal, if the feedback mitigation procedure is stopped, by comparing one or more energy level measurements of frequency components output by the isolation filter of a further candidate signal to respective threshold energy levels.

11. A non-transitory computer-readable medium configured to store instructions thereon that, when executed by one or more processors, cause the one or more processors to perform adaptive feedback reduction in a digital audio signal by:
detecting feedback within a composite digital reference signal that is based upon the digital audio signal based on:
an energy level measurement of a fundamental frequency component of a candidate signal of the composite digital reference signal satisfying a first predetermined threshold energy value, and
a plurality of previous energy level measurements of the fundamental frequency component of the candidate signal over a time interval satisfying a second predetermined threshold energy value; and
executing, based upon detecting the feedback within the composite digital reference signal, a feedback mitigation procedure to reduce the feedback in the digital audio signal.

12. The non-transitory computer-readable medium of claim 11, wherein the executing the feedback mitigation procedure comprises at least one of:
applying a notch filter to the digital audio signal at a notch frequency corresponding to that of the fundamental frequency component of the candidate signal, or
reducing a gain applied to the digital audio signal.

13. The non-transitory computer-readable medium of claim 11, wherein the instructions, when executed by one or more processors, further cause the one or more processors to, after executing the feedback mitigation procedure, execute a release procedure to discontinue execution of the feedback mitigation procedure by sequentially releasing one or more of a set of notch filters currently applied to the digital audio signal.

14. The method of claim 13, wherein the releasing the one or more of the set of notch filters currently applied to the digital audio signal is based upon an attenuation value provided by each of the set of notch filters.

15. The non-transitory computer-readable medium of claim 11, wherein the instructions, when executed by one or more processors, further cause the one or more processors to determine the candidate signal by identifying, as the candidate signal, a frequency component of the composite digital reference signal having a maximum energy level measurement value.

16. The non-transitory computer-readable medium of claim 11, wherein the instructions, when executed by one or more processors, further cause the one or more processors to:
extract, via an isolation filter, the fundamental frequency component of the candidate signal;
selectively extract, via the isolation filter and based upon a frequency of the fundamental frequency component of the candidate signal, either an upper-harmonic frequency component having an upper harmonic frequency or a lower-harmonic frequency component of the candidate signal having a lower harmonic frequency; and
extract, via the isolation filter, an intermediate frequency component of the candidate signal having a frequency that is: (i) between the frequency of the fundamental frequency component and the upper harmonic frequency when the upper-harmonic frequency component is extracted, or (ii) between the frequency of the fundamental frequency component and the lower harmonic frequency when the lower-harmonic frequency component is extracted.

17. The non-transitory computer-readable medium of claim 16, wherein the detecting the feedback within the composite digital reference signal is further based upon an energy level measurement of the intermediate frequency component of the candidate signal and one of: (i) the upper-harmonic frequency component, or (ii) the lower-harmonic frequency component.

18. The non-transitory computer-readable medium of claim 11, wherein the detecting the feedback within the composite digital reference signal is further based upon a computation of:
a ratio of an energy level measurement of a fundamental frequency component of the candidate signal to a harmonic energy level measurement value of the candidate signal,
a ratio of an energy level measurement of an intermediate frequency component of the candidate signal to a harmonic energy level measurement value of the candidate signal, and
a stability of a fundamental frequency of the fundamental frequency component of the candidate signal over a predetermined time period.

19. The non-transitory computer-readable medium of claim 11, wherein the instructions, when executed by one or more processors, further cause the one or more processors to:
after executing the feedback mitigation procedure to reduce feedback in the digital audio signal, execute a release procedure to discontinue execution of the feedback mitigation procedure based upon one or more external inputs being indicative of a change in a system state that impacts generation of the digital reference signal.

20. The non-transitory computer-readable medium of claim 11, wherein the executing the feedback mitigation procedure comprises applying a notch filter to the digital audio signal at a notch frequency corresponding to that of the fundamental frequency component of the candidate signal, and
wherein the instructions, when executed by one or more processors, further cause the one or more processors to concurrently with executing the feedback mitigation procedure, determine whether to initiate a release procedure to discontinue execution of the feedback mitigation procedure by:
applying, to the composite digital reference signal, an isolation filter having filter parameters that are based upon filter parameters of the applied notch filter; and
determining whether feedback will remain in the audio signal if the feedback mitigation procedure is stopped by comparing one or more energy level measurements of frequency components output by the isolation filter of a further candidate signal to respective threshold energy levels.
